(19) United States
(12) Patent Application Publication
(10) Pub. No.: US 2019/0198321 A1
(43) Pub. Date: Jun. 27, 2019

(54) FILM FORMING METHOD

(71) Applicant: TOKYO ELECTRON LIMITED, Tokyo (JP)

(72) Inventors: Yoshihide KIHARA, Miyagi (JP); Takahiro YOKOYAMA, Miyagi (JP)

(73) Assignee: TOKYO ELECTRON LIMITED, Tokyo (JP)

(21) Appl. No.: 16/232,243

(22) Filed: Dec. 26, 2018

(30) Foreign Application Priority Data
Dec. 25, 2017 (JP) 2017-247937

(51) Int. Cl. H01L 21/033; H01L 21/02; H01L 21/311

(52) U.S. Cl. CPC H01L 21/0338; H01L 21/02274; H01L 21/0228; H01L 21/31116; H01L 21/0335; H01L 21/0337; H01L 21/02334

(57) ABSTRACT

A film forming method includes placing a substrate formed with a pattern on a pedestal provided in a space configured to perform a plasma processing therein under a reduced pressure environment; supplying radio-frequency electric power using an upper electrode disposed to face the pedestal in the space; and repeatedly executing a sequence including forming a film on the pattern of the substrate and cleaning the space by supplying electric power only to the upper electrode so as to generate plasma in the space.

### CROSS-REFERENCE TO RELATED APPLICATIONS

This application is based on and claims priority from Japanese Patent Application No. 2017-247937, filed on Dec. 25, 2017, with the Japan Patent Office, the disclosures of which are incorporated herein in their entireties by reference.

### TECHNICAL FIELD

Exemplary embodiments of the present disclosure relate to a film forming method.

### BACKGROUND

According to the miniaturization associated with high integration of electronic devices, it is required to control the minimum line width (a critical dimension (CD)) with high precision in a pattern formation on a substrate. Fluctuation of the minimum line width in plasma etching may be generally caused, for example, when the states of the surfaces of components of a plasma processing apparatus exposed to a processing space where plasma is generated (e.g., the inner wall surface of the processing container configured to generate plasma and the inner wall surfaces of various pipes) change. Various technologies have been developed to cope with the state change of the surfaces of the components of such a plasma processing apparatus (see, e.g., Japanese Patent Laid-open Publication Nos. 2016-072625, 2014-053644, and 2017-073535).

### SUMMARY

In one aspect, a film forming method includes placing a substrate formed with a pattern on a pedestal provided in a space configured to perform a plasma processing therein under a reduced pressure environment; supplying radio-frequency electric power using an upper electrode disposed to face the pedestal in the space; and repeatedly executing a sequence including forming a film on the pattern of the substrate and cleaning the space by supplying electric power only to the upper electrode so as to generate plasma in the space.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a flow diagram illustrating a method of processing a substrate according to an embodiment.

FIG. 2 is a view illustrating an exemplary plasma processing apparatus according to an embodiment, which is used for executing the method illustrated in FIG. 1.

FIG. 3 is a view schematically illustrating some of a plurality of regions on a main surface of a substrate divided in a method of processing the processing target substrate according to an embodiment.

FIGS. 4A to 4D are cross-sectional views illustrating states of a substrate before and after carrying out respective steps illustrated in FIG. 1.

FIGS. 5A to 5C are cross-sectional views illustrating states of a substrate after carrying out respective steps of the method illustrated in FIG. 1.

FIG. 6 is a diagram representing states of supply of a gas and supply of radio-frequency power during execution of respective steps of the method illustrated in FIG. 1.

FIGS. 7A to 7C are views schematically illustrating states of formation of a protective film in the method illustrated in FIG. 1.

FIG. 8 is a diagram schematically representing a relationship between a film thickness of a protective film formed by the method illustrated in FIG. 1 and a temperature of the main surface of a substrate.

FIGS. 9A to 9C are views illustrating an etching principle of an etching target layer in the method illustrated in FIG. 1.

FIG. 10 is a view illustrating aspects of film formation inside the processing container illustrated in FIG. 2.

FIG. 11 is a diagram representing a correlation between an execution time of the cleaning step illustrated in FIG. 1 or radio-frequency power used in the cleaning step illustrated in FIG. 1 and a residual thickness of a film after the cleaning.

FIG. 12 is a diagram representing a correlation between a position in the processing container illustrated in FIG. 2 and a plasma density.

FIG. 13 is a diagram representing a correlation between a position in the processing container illustrated in FIG. 2 and a plasma density.

FIG. 14 is a diagram representing a breakdown of a processing time of each substrate.

FIG. 15 is a diagram representing a correlation between the number of repetition times of a thin film forming step and a processing time for each substrate.

FIG. 16 is a schematic view of a gas supply system.

FIG. 17 is a schematic cross-sectional view of an upper electrode in a case where the gas supply system illustrated in FIG. 16 is used.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In a plasma processing, particles, which may cause a product defect, may be generated. The particles may be generated from the surfaces of components of the plasma processing apparatus exposed in the processing space and adhere to a wafer, leading to a product defect. Since the particles hinder transfer when adhering onto a pattern, the particles may hinder realization of a highly precise minimum line width. Therefore, what is required for miniaturization associated with high integration in pattern formation on a substrate is a technique for suppressing generation of particles.

In one aspect, a film forming method includes placing a substrate formed with a pattern on a pedestal provided in a space configured to perform a plasma processing therein under a reduced pressure environment; supplying radio-frequency electric power using an upper electrode disposed to face the pedestal in the space; and repeatedly executing a sequence including forming a film on the pattern of the substrate and cleaning the space by supplying electric power only to the upper electrode so as to generate plasma in the space.

In the film forming method, the space in which the first step has been performed is cleaned every time the deposited film is formed by executing the first step once, and thus it becomes easy to remove the deposited film formed in this space.

In an embodiment, the forming includes supplying a first gas including a material of a precursor to the space so as to cause the precursor to be adsorbed to the surface of the pattern, and generating plasma of the second gas so as to supply the plasma to the precursor.

In this manner, in the forming, the deposited film is formed on a surface of the pattern of the substrate first by causing the precursor to be adsorbed to the surface of the pattern of the substrate by the first gas including the material of the precursor, and then supplying plasma of a second gas to the precursor. Therefore, the deposited film may be formed on the surface of the pattern of the substrate by a method which is the same as an atomic layer deposition (ALD) method.

In an embodiment, the first gas is an aminosilane-based gas and the second gas contains oxygen or nitrogen. Further, in the second step, plasma of the third gas is generated in the space, and the third gas contains a halogen compound.

In an embodiment, the aminosilane-based gas of the first gas includes aminosilane having 1 to 3 silicon atoms. In addition, in an embodiment, the aminosilane-based gas of the first gas may include aminosilane having 1 to 3 amino groups.

In an embodiment, the first gas contains tungsten halide. In addition, in an embodiment, the first gas contains titanium tetrachloride or tetrakis(dimethylamino)titanium. Also, in an embodiment, the first gas contains halogenated boron.

In an embodiment, the forming (hereinafter, referred to as “step a”) includes supplying a first gas including an electron-donating first substituent (hereinafter, referred to as “gas a1” when used in step a) so as to cause the first substituent to be adsorbed to the surface of the pattern and supplying a second gas including an electron-attracting second substituent (hereinafter, referred to as a gas a2 in the case of being used in step a) to the first substituent.

In this way, in the step a of forming the deposited film, first, the first substituent is adsorbed on the surface of the pattern of the substrate by the gas a1 including the electron-donating first substituent, and a polymerization reaction is generated by supplying the gas a2 including an electron-attracting second substituent to the first substituent, and a deposition film is formed on the surface of the pattern of the substrate by the polymerization reaction.

In an embodiment, the above-mentioned step a forms the film by polymerization reaction of isocyanate and amine, or polymerization reaction of isocyanate and a hydroxyl group-containing compound.

As described above, there is provided a technique for suppressing generation of particles for the purpose of miniaturization associated with high integration in pattern formation on a substrate.

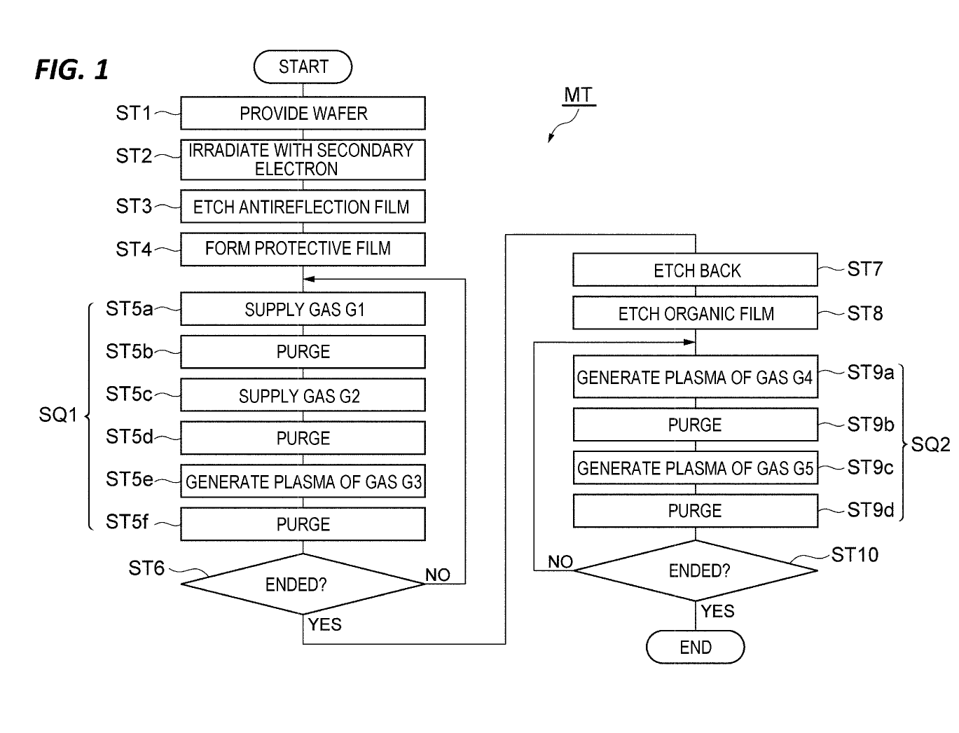

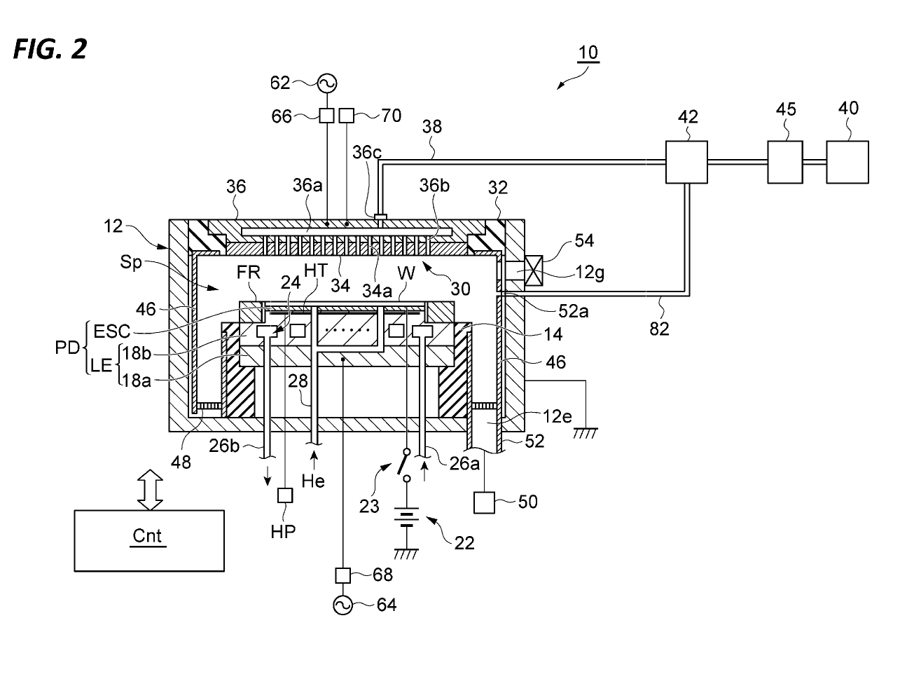

Hereinafter, various embodiments will be described in detail with reference to the accompanying drawings. In each drawing, the same or corresponding components will be denoted by the same symbols. FIG. 1 is a flow chart illustrating a method of processing a substrate (hereinafter, referred to as a “wafer W” in some cases) according to an embodiment. A method MT illustrated in FIG. 1 is an embodiment of a film forming method for forming a film on a substrate. Method MT (the method of processing a substrate) is executed by a plasma processing apparatus 10 illustrated in FIG. 2.

FIG. 2 is a view illustrating an exemplary plasma processing apparatus according to an embodiment, which is used for executing method MT illustrated in FIG. 1. FIG. 2 schematically illustrates a cross-sectional structure of the plasma processing apparatus 10 used in various embodiments of method MT. As illustrated in FIG. 2, the plasma processing apparatus 10 is a plasma etching apparatus including electrodes of parallel flat plates, and is provided with a processing container 12.

The processing container 12 has, for example, a substantially cylindrical shape and defines a processing space Sp. The processing container 12 has, for example, an aluminum material, and an inner wall surface of the processing container 12 is subjected to an anodic oxidation treatment. The processing container 12 is securely grounded.

On the bottom portion of the processing container 12, for example, a substantially cylindrical support unit 14 is provided. The support unit 14 has, for example, an insulating material. The insulating material of the support unit 14 may include oxygen like quartz. The support unit 14 extends vertically (in the direction from the bottom portion toward the ceiling side upper electrode 30) from the bottom portion of the processing container 12 in the processing container 12.

A pedestal PD is provided in the processing container 12. The pedestal PD is supported by the support unit 14. The pedestal PD holds a wafer W on the top surface thereof. The main surface of the wafer W is opposite to the rear surface of the wafer W which is in contact with the top surface of the pedestal PD and faces the upper electrode 30. The pedestal PD includes a lower electrode LE and an electrostatic chuck ESC. The lower electrode LE includes a first plate 18a and a second plate 18b.

The first plate 18a and the second plate 18b have a metal material such as, for example, aluminum, and have, for example, a substantially disc shape. The second plate 18b is provided on the first plate 18a and is electrically connected to the first plate 18a.

On the second plate 18b, an electrostatic chuck ESC is provided. The electrostatic chuck ESC has a structure in which an electrode which is a conductive film is disposed between a pair of insulating layers or between a pair of insulating sheets. A direct current (DC) power supply 22 is electrically connected to the electrode of the electrostatic chuck ESC via a switch 23. When the wafer W is placed on the pedestal PD, the wafer W is in contact with the electrostatic chuck ESC.

The rear surface (the surface opposite to the main surface) of the wafer W is in contact with the electrostatic chuck ESC. The electrostatic chuck ESC attracts the wafer W by an electrostatic force such as, for example, a Coulomb force generated by a DC voltage from the DC power supply 22. As a result, the electrostatic chuck ESC holds the wafer W.

On the peripheral edge portion of the second plate 18b, a focus ring FR is disposed to surround the edge of the wafer W and the electrostatic chuck ESC. The focus ring FR is provided in order to improve etching uniformity. The focus ring FR has a material appropriately selected depending on the material of the etching target film, and may have, for example, a quartz material.

The plasma processing apparatus 10 is provided with a temperature regulation unit HT configured to regulate the temperature of the wafer W. The temperature regulation unit HT is incorporated in the electrostatic chuck ESC. A heater power supply HP is connected to the temperature regulation unit HT. As power is supplied from a heater power supply HP to the temperature regulation unit HT, the temperature of the electrostatic chuck ESC is regulated, and the temperature of the wafer W placed on the electrostatic chuck ESC is regulated. The temperature regulation unit HT may be buried in the second plate 18b.

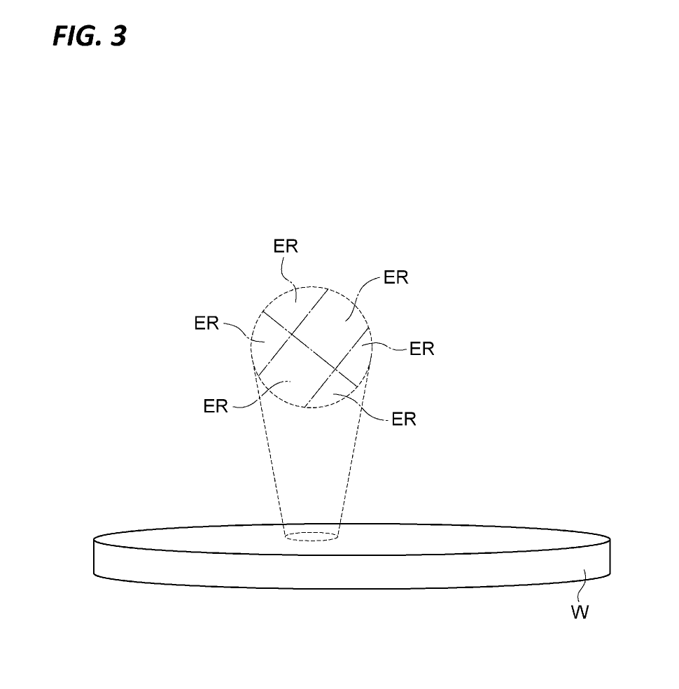

The temperature regulation unit HT includes a plurality of heating elements configured to emit heat and a plurality of temperature sensors each configured to detect the ambient temperature of each of the plurality of heating elements. In the case where the wafer W is positioned and placed on the electrostatic chuck ESC, each of the plurality of heating elements is provided for each of a plurality of regions ER on the main surface of the wafer W, as illustrated in FIG. 3. FIG. 3 is a view schematically showing some of a plurality of regions ER on the main surface of the wafer W divided by method MT as an example. When the wafer W is positioned and placed on the electrostatic chuck ESC, a controller Cnt described later recognizes the plurality of regions ER by causing the heating elements and temperature sensors, which correspond to respective regions ER on the main surface of the wafer W, to be associated with each other. The controller Cnt may identify the heating elements and temperature sensors, which correspond to respective regions ER, based on for example, numbers such as, for example, numerals or characters for respective regions ER. The controller Cnt detects the temperature of one region ER by a temperature sensor provided at a position corresponding to the one region ER, and the temperature of the one region ER is regulated by a heating element provided at a position corresponding to the one region ER. When the wafer W is placed on the electrostatic chuck ESC, the temperature detected by one temperature sensor is the same as the temperature of the region ER on the temperature sensor in the wafer W.

Inside the second plate 18b, a coolant flow path 24 is provided. The coolant flow path 24 constitutes a temperature regulation mechanism. A coolant is supplied to the coolant flow path 24 from a chiller unit (not illustrated) provided outside the processing container 12 via a pipe 26a. The coolant supplied to the coolant flow path 24 is returned to the chiller unit via a pipe 26b. In this manner, the coolant is supplied to the coolant flow path 24 so as to circulate. The temperature of the wafer W supported by the electrostatic chuck ESC is controlled by controlling the temperature of this coolant. The plasma processing apparatus 10 is provided with a gas supply line 28. The gas supply line 28 supplies a heat transfer gas such as, for example, He gas, from the heat transfer gas supply mechanism to a gap between the top surface of the electrostatic chuck ESC and the rear surface of the wafer W.

The plasma processing apparatus 10 includes an upper electrode 30. The upper electrode 30 is provided on the ceiling side in the processing container 12 (the side opposite to the side where the support unit 14 is provided in the processing container 12). The upper electrode 30 is disposed to face the pedestal PD above the pedestal PD.

The lower electrode LE and the upper electrode 30 are installed to be substantially parallel to each other, and form parallel plate electrodes. Between the upper electrode 30 and the lower electrode LE, a processing space Sp is provided in order to perform a plasma processing on the wafer W. The upper electrode 30 is supported in the upper portion of the processing container 12 via an insulative blocking member 32. The insulative blocking member 32 includes an insulating material, and may include oxygen like quartz. The upper electrode 30 may include an electrode plate 34 and an electrode support 36. The electrode plate 34 faces the processing space Sp, and the electrode plate 34 is provided with a plurality of gas ejection ports 34a.

In an embodiment, the electrode plate 34 contains silicon. In another embodiment, the electrode plate 34 may contain silicon oxide (SiO₂).

The electrode support 36 detachably supports the electrode plate 34, and may include a conductive material such as, for example, aluminum. The electrode support 36 may have a water-cooling structure. Inside the electrode support 36, a gas diffusion chamber 36a is provided. A plurality of gas flow holes 36b communicating with the gas ejection ports 34a extend downward from the gas diffusion chamber 36a.

The plasma processing apparatus 10 includes a first radio-frequency power supply 62 and a second radio-frequency power supply 64. The first radio-frequency power supply 62 is a power supply configured to generate first radio-frequency power for plasma generation and generates a radio-frequency power of 27 to 100 MHz, for example, 60 MHz in one example. Further, the first radio-frequency power supply 62 has a pulse specification, and is controllable with, for example, a frequency of 0.1 to 50 kHz and a duty of 5 to 100%.

The first radio-frequency power supply 62 is connected to the upper electrode 30 via a matcher 66. The matcher 66 is a circuit configured to match the output impedance of the first radio-frequency power supply 62 with the input impedance on the load side (the lower electrode LE side). In addition, the first radio-frequency power supply 62 may be connected to the lower electrode LE via the matcher 66.

The second radio-frequency power supply 64 is a power supply configured to generate a second radio-frequency power for drawing ions to the wafer W, that is, a radio-frequency bias power, and generates a radio-frequency bias power having a frequency in the range of 400 kHz to 40.68 MHz, for example, 13.56 MHz. Further, the second radio-frequency power supply 64 has a pulse specification, and is controllable with, for example, a frequency of 0.1 to 50 kHz and a duty of 5 to 100%.

The second radio-frequency power supply 64 is connected to the lower electrode LE via a matcher 68. The matcher 68 is a circuit configured to match the output impedance of the second radio-frequency power supply 64 with the input impedance on the load side (lower electrode LE side).

The plasma processing apparatus 10 further includes a power supply 70. The power supply 70 is connected to the upper electrode 30. The power supply 70 applies, to the upper electrode 30, a voltage for drawing positive ions existing in the processing space Sp into the electrode plate 34. In one example, the power supply 70 is a DC power supply that generates a negative DC voltage. When such a voltage is applied from the power supply 70 to the upper electrode 30, positive ions existing in the processing space Sp collide with the electrode plate 34. As a result, secondary electrons and/or silicon may be emitted from the electrode plate 34.

On bottom portion side in the processing container 12 (the side opposite to the ceiling side in the processing container 12, and the side where the support unit 14 is provided in the processing container 12) and between the sidewall of the processing container 12 and the support unit 14, an exhaust plate 48 is provided. For the exhaust plate 48, for example, an aluminum material may be coated with ceramics such as Y₂O₃. An exhaust port 12e is provided below the exhaust plate 48 and in the processing container 12.

An exhaust device 50 is connected to the exhaust port 12e via an exhaust pipe 52. The exhaust device 50 includes a vacuum pump such as, for example, a turbo molecular pump, and decompresses the processing space Sp of the processing container 12 to a desired degree of vacuum. A carry-in/out port 12g for a wafer W is provided in the sidewall of the processing container 12, and the carry-in/out port 12g is configured to be opened and closed by a gate valve 54.

As will be described later, since the plasma processing apparatus 10 supplies an organic-containing aminosilane-based gas, the plasma processing apparatus 10 includes a pipe that supplies an organic-containing aminosilane-based gas and a post-mix structure configured to separate a piping that supplies another processing gas (e.g., oxygen gas). Since the organic-containing aminosilane-based gas has a relatively high reactivity, when the supply of the organic-containing aminosilane-based gas and the supply of the other process gas are performed by the same pipe, the components of the organic-containing aminosilane-based gas reacts with the components of the other process gas, and a reaction product resulting from this reaction may deposit in the pipe.

The reaction product which has deposited in the pipe is difficult to remove by, for example, cleaning, and when the cause of particles and the position of the pipe are close to the plasma region, abnormal discharge may be caused. Therefore, it is necessary to supply the organic-containing aminosilane-based gas and the supply of the other process gas with separate pipes, respectively. By the post-mix structure of the plasma processing apparatus 10, the supply of the organic-containing aminosilane-based gas and the supply of the other process gas are performed by separate pipes, respectively.

The post-mix structure of the plasma processing apparatus 10 includes at least two pipes (a gas supply pipe 38 and a gas supply pipe 82). To both the gas supply pipe 38 and the gas supply pipe 82, a gas source group 40 is connected via a valve group 42 and a flow rate controller group 45.

The gas source group 40 includes a plurality of gas sources. The plurality of gas sources may include various gas sources such as, for example, a source of an organic-containing aminosilane-based gas (e.g., a gas included in a gas G1), a fluorocarbon-based gas (CₓF_{y} gas (x and y are integers of 1 to 10) (e.g., gases used in steps ST3 and ST7 and a gas included in a gas G4), a source of a gas including oxygen atoms, (e.g., oxygen gas) (e.g., a gas included in a gas G2), a source of a gas including fluorine atoms (e.g., a gas included in a gas G3), a source of a gas including nitrogen atoms (e.g., a gas used in step ST8), a source of a gas including hydrogen atoms (e.g., a gas used in step ST8), and a source of an inert gas such as, for example, Ar gas (e.g., a gas included in a gas G5, a purge gas, and a backflow prevention gas).

As the organic-containing aminosilane-based gas, a gas having a molecular structure having a relatively small number of amino groups may be used. For example, a monoamino silane (H₃—Si—R (R is an amino group which includes an organic and may be substituted) may be used. The above-described organic-containing aminosilane-based gas (a gas included in the gas G1 described later) may include an aminosilane having 1 to 3 silicon atoms, or may include an aminosilane having 1 to 3 amino groups.

The aminosilane having 1 to 3 silicon atoms may be monosilane having 1 to 3 amino groups (monoaminosilane), disilane having 1 to 3 amino groups, or trisilane having 1 to 3 amino groups. Furthermore, the above-mentioned aminosilane may have an amino group which may be substituted. In addition, the above-mentioned amino groups may be substituted by any of methyl, ethyl, propyl, and butyl groups. Furthermore, the above-mentioned methyl, ethyl, propyl or butyl groups may be substituted by a halogen.

As the fluorocarbon-based gas, any fluorocarbon-based gas such as, for example, CF₄ gas, C₄F₆ gas, or C₄F₈ gas may be used. As the inert gas, any gas such as, for example, nitrogen gas, Ar gas, or He gas may be used.

The valve group 42 includes a plurality of valves, and the flow rate controller group 45 includes a plurality of flow rate controllers such as mass flow controllers. Each of the plurality of gas sources of the gas source group 40 is connected to the gas supply pipe 38 and the gas supply pipe 82 via a corresponding valve of the valve group 42 and a corresponding flow controller of the flow controllers 45. Accordingly, the plasma processing apparatus 10 supplies the gases from one or more selected gas sources among the plurality of gas sources of the gas source group 40 into the processing space Sp of the processing container 12 at an individually adjusted flow rate.

The processing container 12 is provided with a gas inlet 36c. The gas inlet 36c is provided above the wafer W placed on the pedestal PD in the processing container 12. The gas inlet 36c is connected to one end of the gas supply pipe 38. The other end of the gas supply pipe 38 is connected to the valve group 42.

The gas inlet 36c is provided in the electrode support 36. The gas inlet 36c guides a fluorocarbon gas-based gas, a gas including oxygen atoms, a gas including fluorine atoms, a gas including nitrogen atoms and hydrogen atoms, Ar gas, a purge gas (a gas including, e.g., an inert gas), a backflow prevention gas (a gas including, e.g., an inert gas) into the processing space Sp via the gas diffusion chamber 36a. The above-mentioned various gases supplied from the gas inlet 36c to the processing space Sp via the gas diffusion chamber 36a are supplied to the space region above the wafer W (between the wafer W and the upper electrode 30).

A gas inlet 52a is provided in the processing container 12. The gas inlet 52a is provided on a side of the wafer W placed on the pedestal PD in the processing container 12. The gas inlet 52a is connected to one end of the gas supply pipe 82. The other end of the gas supply pipe 82 is connected to the valve group 42.

The gas inlet 52a is provided in the sidewall of the processing container 12. The gas inlet 52a guides a gas including, for example, an organic-containing aminosilane-based gas and a backflow prevention gas (a gas including, e.g., an inert gas) into the processing space Sp. The above-mentioned various gases supplied to the processing space Sp from the gas inlet 52a are supplied from the lateral side of the wafer W to the space region on the wafer W (between the wafer W and the upper electrode 30).

The gas supply pipe 38 connected to the gas inlet 36c and the gas supply pipe 82 connected to the gas inlet 52a do not intersect each other. In other words, the gas supply path including the gas inlet 36c and the gas supply pipe 38 and the gas supply path including the gas inlet 52a and the gas supply pipe 82 do not intersect each other.

In the plasma processing apparatus 10, a deposition shield 46 is detachably installed along the inner wall of the processing container 12. The deposition shield 46 is also installed on the outer periphery of the support unit 14. The deposition shield 46 prevents etching by-products (deposits) from adhering to the processing container 12, and in the deposition shield 46, for example, ceramics such as Y₂O₃ may be coated on an aluminum material. In addition to Y₂O₃, the deposition shield may have a material including oxygen, like quartz, for example.

The controller Cnt is a computer including, for example, a processor, a storage unit, an input device, and a display device, and controls each unit of the plasma processing apparatus 10 illustrated in FIG. 2. In the plasma processing apparatus 10, the controller Cnt is connected to, for example, the valve group 42, the flow rate controller group 45, the exhaust device 50, the first radio-frequency power supply 62, the matcher 66, the second radio-frequency power supply 64, the matcher 68, the power supply 70, the heater power supply HP, and the chiller unit.

The controller Cnt operates in accordance with a computer program (a program based on an input recipe) for controlling each unit of the plasma processing apparatus 10 in each step of method MT illustrated in FIG. 1, and sends out a control signal. Each unit of the plasma processing apparatus 10 is controlled by a control signal from the controller Cnt.

Specifically, in the plasma processing apparatus 10 illustrated in FIG. 2, the controller controls, for example, the selection and flow rate of a gas supplied from the gas source group 40, the exhaust of the exhaust device 50, the supply of power from the first radio-frequency power supply 62 and the second radio-frequency power supply 64, voltage application from the power supply 70, the supply of power of the heater power supply HP, and the flow rate and temperature from the chiller unit.

Each step of method MT for processing a substrate disclosed in this specification may be executed by operating each unit of the plasma processing apparatus 10 by control performed by the controller Cnt. In the storage unit of the controller Cnt, a computer program for executing method MT and various data used for executing method MT are readably stored.

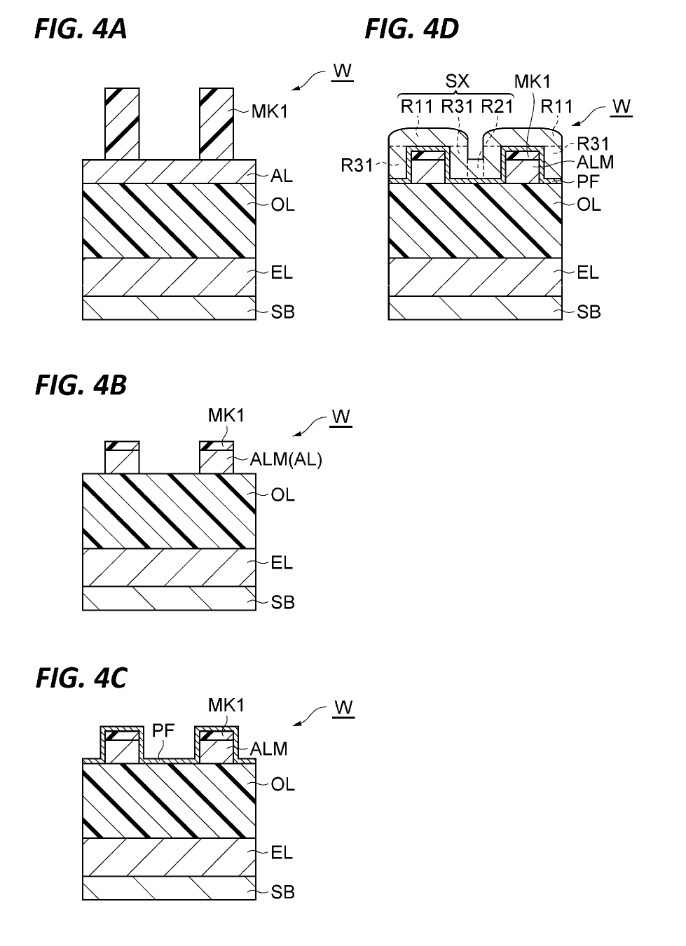

Referring to FIG. 1 again, method MT will be described in detail. Hereinafter, an example in which the plasma processing apparatus 10 is used for executing method MT will be described. In addition, in the following description, reference is made to FIGS. 4 to 10 together with FIGS. 1 to 3.

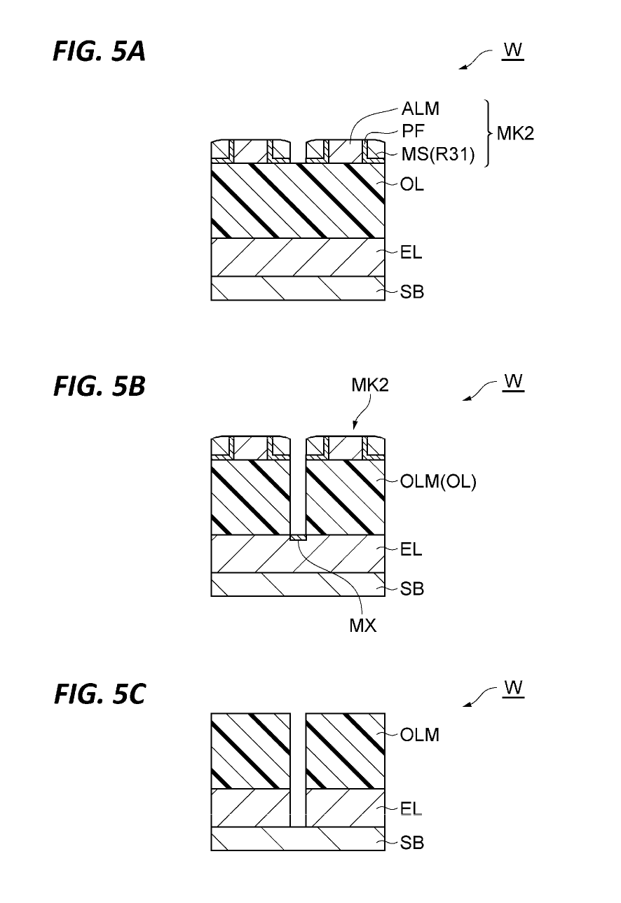

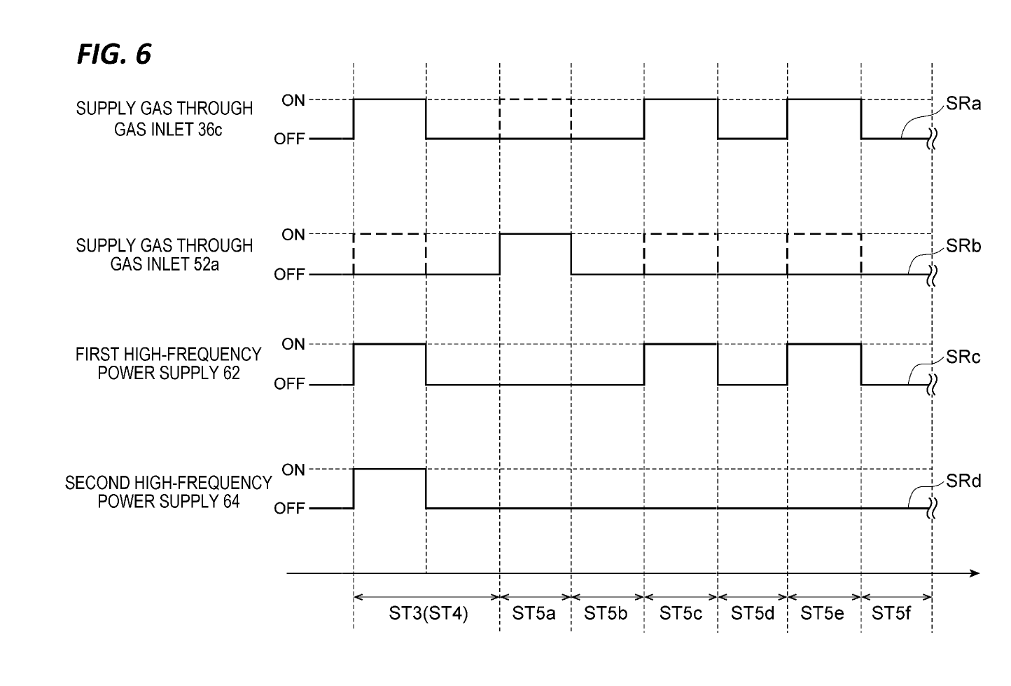

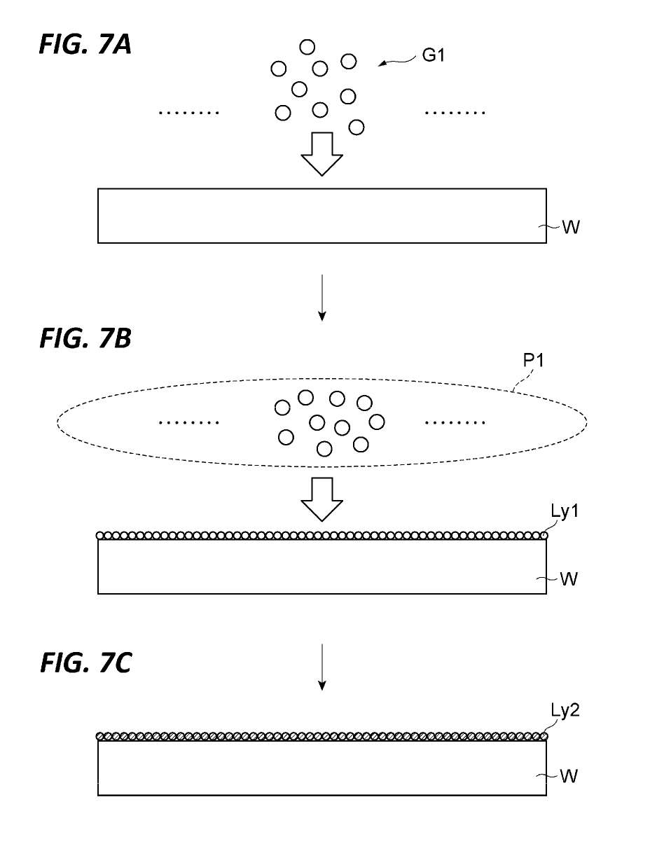

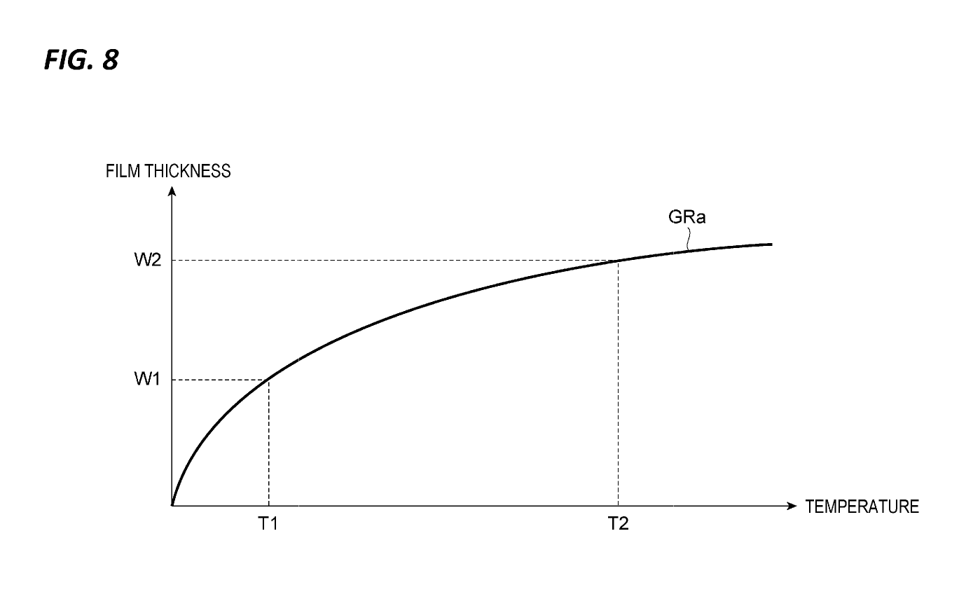

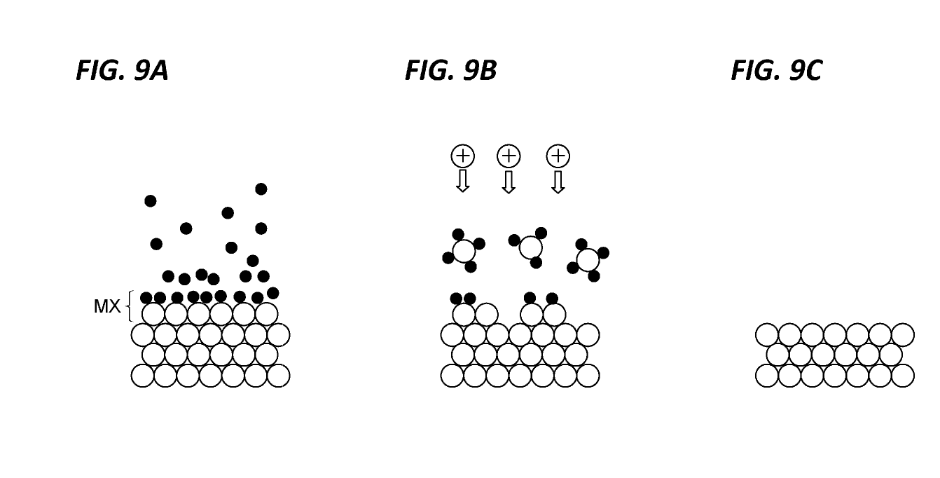

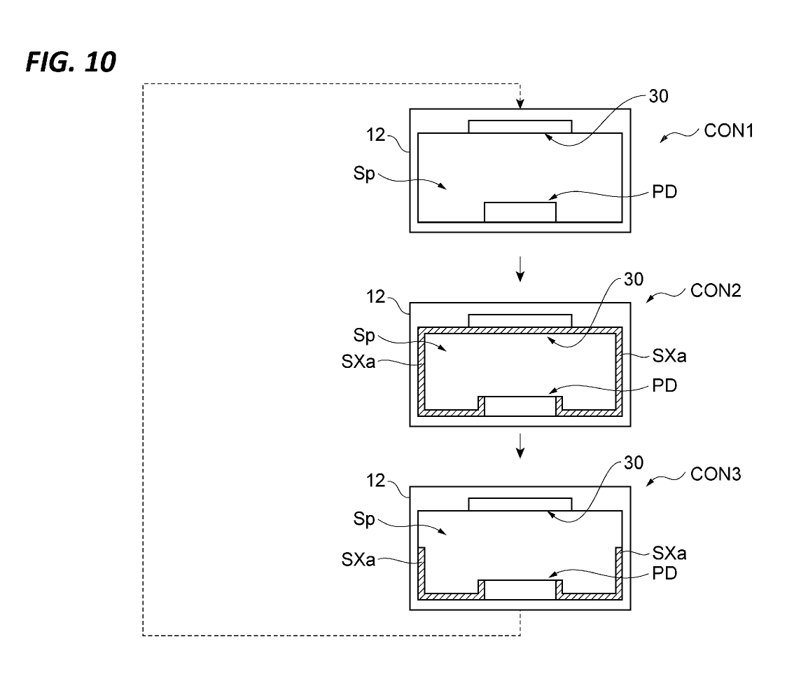

FIGS. 4A to 4D are cross-sectional views illustrating states of a wafer before and after carrying out respective steps illustrated in FIG. 1. FIGS. 5A to 5C are cross-sectional views illustrating states of a wafer W after carrying out respective steps of the method illustrated in FIG. 1. FIG. 6 is a diagram representing states of supply of a gas and supply of radio-frequency power during execution of respective steps of method MT illustrated in FIG. 1. FIGS. 7A to 7C are views schematically illustrating states of formation of a protective film SX in method MT illustrated in FIG. 1. FIG. 8 is a view schematically illustrating relationship between the film thickness of a protective film SX formed by the film forming process (sequence SQ1 and step ST6) of method MT illustrated in FIG. 1 and the temperature of the main surface of the wafer W. FIGS. 9A to 9C are views illustrating a principle of etching an etching target layer EL in method MT illustrated in FIG. 1. FIG. 10 is a view illustrating the state of forming a film inside the processing container 12.

Method MT is a film forming method. A film is formed on a pattern formed on a surface of a wafer W (a pattern defined by unevenness formed on the surface of the wafer W and defined by, for example, a mask MK1 to be described later). The wafer W is placed on the pedestal PD in a processing space Sp in which a plasma processing is performed under a reduced pressure environment. As described above, in the plasma processing apparatus 10, the upper electrode 30 which faces the pedestal PD and supplies radio-frequency power is disposed in the processing space Sp. As illustrated in FIG. 1, method MT includes steps ST1 to ST10. Method MT includes a sequence SQ1 and a sequence SQ2. First, in step ST1, the wafer W illustrated in FIG. 4A is provided as the wafer W illustrated in FIG. 2. In step ST1, as illustrated in a state CON1 in FIG. 10, the surfaces of all the components of the plasma processing apparatus 10 inside the processing container 12 (e.g., the inner wall surface of the processing container 12 configured to generate plasma (hereinafter, also referred to as simply an inner surface of the processing container 12)) are exposed in the processing space Sp.

As illustrated in FIG. 4A, the wafer W provided in step ST1 includes a substrate SB, an etching target layer EL, an organic film OL, an antireflection film AL, and a mask MK1. The etching target layer EL is provided on the substrate SB. The etching target layer EL is a layer having a material that is selectively etched with respect to the organic film OL, and an insulating film is used therefor. The etching target layer EL may include, for example, silicon oxide. In addition, the etching target layer EL may include other materials such as, for example, polycrystalline silicon in some cases.

The organic film OL is provided on the etching target layer EL. The organic film OL is a layer including carbon, and is, for example, a spin-on hard mask (SOH) layer. The antireflection film AL is a silicon-containing antireflection film provided on the organic film OL. The mask MK1 is provided on the antireflection film AL. The mask MK1 is a resist mask having a resist material, and is manufactured by patterning a resist layer by a photolithography technique. The mask MK1 partially covers the antireflection film AL. The mask MK1 defines an opening for partially exposing the antireflection film AL. The pattern of the mask MK1 may include a line-and-space pattern. In addition, the mask MK1 can have a pattern with a circular opening in plan view. Alternatively, the mask MK1 may have a pattern with an elliptical opening in plan view.

In step ST1, the wafer W illustrated FIG. 4A is provided, and the wafer W is accommodated in the processing space Sp of the processing container 12 of the plasma processing apparatus 10 and placed on the pedestal PD.

In step ST2 subsequent to step ST1, the wafer W is irradiated with secondary electrons. Specifically, as hydrogen gas and rare gas are supplied into the processing space Sp of the processing container 12 from the gas inlet 36c via the gas supply pipe 38 and radio-frequency power is supplied from the first radio-frequency power supply 62, plasma is generated. Further, a negative DC voltage is applied to the upper electrode 30 by the power supply 70. As a result, positive ions in the processing space Sp are drawn into the upper electrode 30, and the positive ions collide with the upper electrode 30. As the positive ions collide with the upper electrode 30, secondary electrons are released from the upper electrode 30. The released secondary electrons modify the mask MK1. When step ST2 is ended, the processing space Sp of the processing container 12 is purged.

When the level of the absolute value of the negative DC voltage applied to the upper electrode 30 is high, the positive ions collide with the electrode plate 34, whereby silicon which is a constituent material of the electrode plate 34 is released together with secondary electrons. The released silicon is combined with oxygen released from the components of the plasma processing apparatus 10 exposed to the plasma. The oxygen is released from members such as, for example, the support unit 14, the insulative blocking member 32, and the deposition shield 46. By the combination of silicon and the oxygen, a compound of silicon oxide is formed, and the compound of silicon oxide is deposited on the wafer W to cover and protect the mask MK1.

Damage to the mask MK1 by subsequent steps is suppressed by the modification and protection effects. In step ST2, in order to obtain the modification by irradiation with secondary electrons and form a protective film, the bias power of the second radio-frequency power supply 64 may be minimized so as to suppress the release of silicon.

In step ST3 subsequent to step ST2, the antireflection film AL is etched. Specifically, as represented by symbol SRa in FIG. 6, from a gas source selected among the plurality of gas sources of the gas source group 40, a gas including a fluorocarbon-based gas is supplied into the processing space Sp of the processing container 12 through the gas supply pipe 38 and the gas inlet 36c. In this case, no gas is supplied from the gas inlet 52a as represented by symbol SRb in FIG. 6, or the backflow prevention gas is supplied into the processing space Sp of the processing container 12 through the gas supply pipe 82 and the gas inlet 52a as represented by a broken line of symbol SRb in FIG. 6.

In addition, radio-frequency power is supplied from the first radio-frequency power supply 62 as represented by symbol SRc in FIG. 6, and radio-frequency bias power is supplied from the second radio-frequency power supply 64 as represented by symbol SRd in FIG. 6. By operating the exhaust device 50, the pressure in the processing space Sp of the processing container 12 is set to a preset pressure. As a result, plasma of fluorocarbon-based gas is generated.

Active species including fluorine in the generated plasma etches a region, exposed from the mask MK1, of the entire region of the antireflection film AL. By this etching, a mask ALM is formed from the antireflection film AL as illustrated in FIG. 4B. The mask for the organic film OL formed in step ST3 includes the mask MK1 and the mask ALM.

In step ST4 subsequent to step ST3, as illustrated in FIG. 4C, in the same manner as step ST2, a silicon oxide protective film PF is formed on the surface of the mask MK1, the surface of the mask ALM, and the surface of the organic film OL. When step ST4 is ended, the inside of the processing space Sp of the processing container 12 is purged. After step ST3, sequence SQ1 may be executed without performing step ST4.

Subsequent to step ST4, in method MT shown in FIG. 1, sequence SQ1 is executed one or more times. Sequence SQ1 includes steps ST5a to ST5f. Sequence SQ1 includes a first step (steps ST5a to ST5d) of forming a deposited film (a thin film forming a protective film SX) on the pattern of the wafer W and a second step (steps ST5e to ST5f) of cleaning the processing space Sp by generating plasma in the processing space Sp by supplying power only to the upper electrode 30 subsequent to sequence SQ2. As illustrated in FIG. 4B, the film forming step including sequence SQ1 and step ST6 includes a cleaning step (step ST5e and step ST5f) for cleaning a region, located above the wafer W (the ceiling side in the processing container 12), of the processing container 12 consequent to the film forming step, together with the film forming step (step ST5a, step ST5b, step ST5c, and step ST5d for conformally forming a thin film (a film forming the protective film SX) on the main surface of the wafer W accommodated in the processing container 12 of the plasma processing apparatus 10 by a method which is the same as an ALD method.

In the film forming step, sequence SQ1 including the thin film forming step and the cleaning step is repeatedly performed through step ST6 so as to form the protective film SX on the main surface of the wafer W, as illustrated in FIG. 4D. When sequence SQ1 is executed once, a thin film (a film forming the protective film SX) is formed on the main surface of the wafer W by executing the thin film forming step, and the portion, located in the upper portion of the processing container 12 (on the ceiling side in the processing container 12), of the film formed inside the processing container 12 due to the formation of the film (the thin film SXa illustrated in FIG. 10) is removed by execution of the cleaning step.

In step ST5a, a first gas (gas G1) including the material of a precursor (layer Ly1) is supplied to the processing space Sp and the precursor is adsorbed to the surface of a pattern (the pattern defined by the mask MK1). In step ST5a, the gas G1 is introduced into the processing space Sp of the processing container 12. Specifically, as represented by symbol SRb in FIG. 6, from a gas source selected among the plurality of gas sources of the gas source group 40, the gas G1 is supplied into the processing space Sp of the processing container 12 through the gas supply pipe 82 and the gas inlet 52a. In this case, no gas is supplied from the gas inlet 36 as represented by symbol SRa in FIG. 6, or the backflow prevention gas is supplied into the processing space Sp of the processing container 12 through the gas supply pipe 38 and the gas inlet 36 as represented by a broken line of symbol SRa in FIG. 6.

In step ST5a, the plasma of the gas G1 is not generated as represented by symbols SRc and SRd in FIG. 6. The gas G1 is, for example, an organic-containing aminosilane-based gas. The gas G1 is an organic-containing aminosilane-based gas and includes monoaminosilane (H₃—Si—R (R is an amino group)).

As illustrated in FIG. 7A, molecules of the gas G1 adhere to the main surface of the wafer W as a reaction precursor. The molecules of the gas G1 (e.g., monoaminosilane) adheres to the main surface of the wafer W by chemical adsorption based on chemical bonding, and plasma is not used. In step ST5a, the temperature of the wafer W is about 0° C. or more and about the glass transition temperature of the material included in the mask MK1 (e.g., about 200° C. or less).

It is also possible to use gases other than the monoamino silane as long as they adhere to the surface by chemical bonding in this temperature range and contain silicon. Since the diaminosilane (H₂—Si—R₂ (R is an amino group)) and triaminosilane (H—Si—R₃ (R is an amino group)) have molecular structures more complicated than the monoaminosilane, a heat treatment may also be performed on the diaminosilane and the triaminosilane in order to self-decompose amino groups in some cases in order to implement uniform film formation when the diaminosilane and the triaminosilane are used as the gas G1.

The reason why the monoaminosilane-based gas is selected as the gas G1 is that since monoaminosilane has a relatively high electronegativity and a molecular structure having polarity, chemisorption can be relatively easily performed. The layer Ly1 (see, e.g., FIG. 7B) formed by the molecules of the gas G1 adhering to the main surface of the wafer W becomes a state close to a monomolecular layer (a single layer) since the corresponding adsorption is chemisorption.

The smaller the amino group R of the monoaminosilane, the smaller the molecular structure of the molecules adsorbed on the main surface of the wafer W. Thus, steric hindrance caused due to the size of the molecules is reduced, and thus the molecules of the gas G1 uniformly adsorb on the main surface of the wafer W, and the layer Ly1 is being formed in a uniform film thickness with respect to the main surface of the wafer W. For example, the reaction precursor H₃—Si—O is formed by the reaction of the monoaminosilane (H₃—Si—R) included in the gas G1 with the OH groups on the main surface of the wafer W, and thus the layer Ly1 which is a monomolecular layer of H₃—Si-A layer Ly1 is formed. Therefore, the layer Ly1 of the reaction precursor is conformally formed in a uniform film thickness without relying on the pattern density of the wafer W with respect to the main surface of the wafer W.

In step ST5b subsequent to step ST5a, the processing space Sp of the processing container 12 is purged. Specifically, the gas G1 supplied in step ST5a is exhausted. In step ST5b, an inert gas such as, for example, nitrogen gas may be supplied into the processing space Sp of the processing container 12 as a purge gas. That is, purge in step ST5b may be either gas purge that causes the inert gas to flow into the processing space Sp of the processing container 12, or purge that is performed as air purge. In step ST5b, molecules excessively adhering on the wafer W may also be removed. As described above, the layer Ly1 of the reaction precursor becomes an extremely thin monomolecular layer.

Step ST5c subsequent to step ST5b is a step of generating plasma of the second gas (gas G2) and supplying the plasma to the precursor (the precursor which is formed in step ST5a and is the layer Ly1). In step ST5c, the plasma P1 of the gas G2 is generated in the processing space Sp of the processing container 12. In step ST5c, the temperature of the wafer W when the plasma P1 of the gas G2 is generated is 0° C. or higher and is equal to or lower than the glass transition temperature of the material included in the mask MK1 (e.g., 200° C. or lower). Specifically, as represented by symbol SRa in FIG. 6, from a gas source selected among the plurality of gas sources of the gas source group 40, the gas G2 including oxygen O is supplied into the processing space Sp of the processing container 12 through the gas supply pipe 38 and the gas inlet 36c. The gas G2 includes oxygen or nitrogen. The gas G2 may include, for example, O₂ gas (oxygen gas). In this case, no gas is supplied from the gas inlet 52a as represented by symbol SRb in FIG. 6, or the backflow prevention gas is supplied into the processing space Sp of the processing container 12 through the gas supply pipe 82 and the gas inlet 52a as represented by a broken line of symbol SRb in FIG. 6.

In addition, radio-frequency power is supplied from the first radio-frequency power supply 62 as represented by symbol SRc in FIG. 6, but the bias power of the second radio-frequency power supply 64 is not applied as represented by symbol SRd in FIG. 6. By operating the exhaust device 50, the pressure in the processing space Sp of the processing container 12 is set to a preset pressure. It is also possible to generate plasma using only the second radio-frequency power supply 64 without using the first radio-frequency power supply 62.

As described above, the molecules adhering to the main surface of the wafer W by execution of step ST5a (molecules forming the monomolecular layer of the layer Ly1) includes bonds between silicon and hydrogen. The bonding energy between silicon and hydrogen is lower than the bonding energy between silicon and oxygen. Therefore, as illustrated in FIG. 7B, when the plasma P1 of the gas G2 including oxygen gas is generated, active species of oxygen, for example, oxygen radicals are generated, the hydrogen of the molecules forming the monomolecular layer of the layer Ly1, and the hydrogen of the molecules forming a monomolecular layer is replaced by oxygen, whereby a layer Ly2 which is silicon oxide is formed as a monomolecular layer, as illustrated in FIG. 7C.

In step ST5d subsequent to step ST5c, the processing space Sp of the processing container 12 is purged. Specifically, the gas G2 supplied in step ST5c is exhausted. In step ST5d, an inert gas such as, for example, nitrogen gas may be supplied into the processing space Sp of the processing container 12 as a purge gas. That is, the purge in step ST5d may be either gas purge that causes the inert gas to flow into the processing space Sp of the processing container 12, or purge that is performed as air purge.

As described above, purge is performed in step ST5b, and hydrogen in the molecules forming the layer Ly1 is replaced with oxygen in step ST5c subsequent to step ST5b. Therefore, by executing the thin film forming step (step ST5a to step ST5d), a thin film (a film forming the protective film SX) having the film thickness in the level of an atomic layer is formed on the main surface of the wafer W. By performing one thin film forming step, as in the ALD method, a layer Ly2 of silicon oxide is conformally formed on the main surface of the wafer W in a thin and uniform film thickness regardless of the roughness and fineness of the mask MK1. Further, by executing the thin film forming step, a thin film SXa adheres to the inner surface of the processing container 12, as illustrated in the state CON2 in FIG. 10.

Step ST5e subsequent to step ST5d cleans a region above the wafer W in the processing container 12. More specifically, step ST5e cleans the upper electrode 30 side surface inside the processing container 12. In step ST5e, a portion, attached to the upper electrode 30 side surface, of the thin film SXa attached to the inner surface of the processing container 12 (a portion in the processing container 12 above the wafer W) by execution of the thin film forming step is removed as illustrated in the state CON3 in FIG. 10.

In step ST5e, the plasma of the third gas (gas G3) is generated in the processing space Sp. In step ST5e, the plasma of the gas G3 is generated in the processing space Sp of the processing container 12. In step ST5e, the plasma of the gas G3 is generated in the processing container 12 using radio-frequency electric power supplied from the upper electrode 30 above the wafer W. In step ST5e, no bias voltage using the second radio-frequency power supply 64 is applied. Specifically, as represented by symbol SRa in FIG. 6, from a gas source selected among the plurality of gas sources of the gas source group 40, the gas G3 is supplied into the processing space Sp of the processing container 12 through the gas supply pipe 38 and the gas inlet 36c. In this case, no gas is supplied from the gas inlet 52a as represented by symbol SRb in FIG. 6, or the backflow prevention gas is supplied into the processing space Sp of the processing container 12 through the gas supply pipe 82 and the gas inlet 52a as represented by a broken line of symbol SRb in FIG. 6.

In step ST5e, the following process conditions (hereinafter, referred to as a “condition group CND”) are used. That is, the condition ground CND includes a condition that radio-frequency power is supplied from the first radio-frequency power supply 62 as represented by symbol SRc in FIG. 6, but the bias voltage of the second radio-frequency power supply 64 is not applied as represented by symbol SRd in FIG. 6. The condition group CND further includes a wide gap condition. In the present description, the wide gap condition means a state where the electrode interval is set to be 30 mm or more. For example, under the condition of a pressure of 100 mTorr, reduction in fluctuation of electron or ion density depending on the gap length was experimentally confirmed when the electrode interval is less than 30 mm. Therefore, the electrode interval may be at least 30 [mm]. The condition group CND further includes a condition that the pressure in the processing space Sp of the processing container 12 is set to a relatively high preset pressure by operating the exhaust device 50. In the present description, the high pressure means a pressure of about 100 mTorr or more. Under the pressure of 100 mTorr or more, a mean free path is 1 mm or less, the incidence of radicals or ions to the wafer W side is sufficiently reduced, and the etching rate on the wafer W side is suppressed.

The etching rate in the cleaning in step ST5e is relatively higher in the upper electrode 30 side (the upper portion in the processing container 12) than in the wafer W side (the lower portion in the processing container 12) by the process condition (condition group CND) in step ST5e. As described above, the condition group CND includes a condition for supplying only the radio-frequency power from the first radio-frequency power supply 62, a condition for setting the pressure in the processing space Sp of the processing container 12 to a relatively high pressure, a wide gap condition.

The plasma density and the electron density may be unevenly distributed to the upper electrode 30 side under the condition that the high frequency power is supplied only from the first radio-frequency power supply 62, in the condition group CND. The respective density distributions of the plasma density and the electron density are distributed more unevenly on the upper electrode 30 side depending on the condition for setting the pressure in the processing space Sp of the processing container 12 to a relatively high pressure and the wide gap condition, in the condition group CND.

The sheath width varies according to the fluctuation of electron density and the sheath voltage is determined by the anode/cathode ratio. In the present description, the anode/cathode ratio means an area ratio. For example, the anode/cathode ratio may mean the ratio of the total areas obtained by summing the respective areas of the upper electrode 30 and the lower electrode LE and the respective areas of portions, which communicate with the upper and lower electrodes, respectively (which have the same potentials as respective electrodes). In the condition group CND, the cathode includes the upper electrode 30, and the anode includes the wafer W (the lower electrode LE) and the inner wall in the processing container 12. Since the anode side region is relatively wider than the cathode side region, the sheath voltage is also reduced.

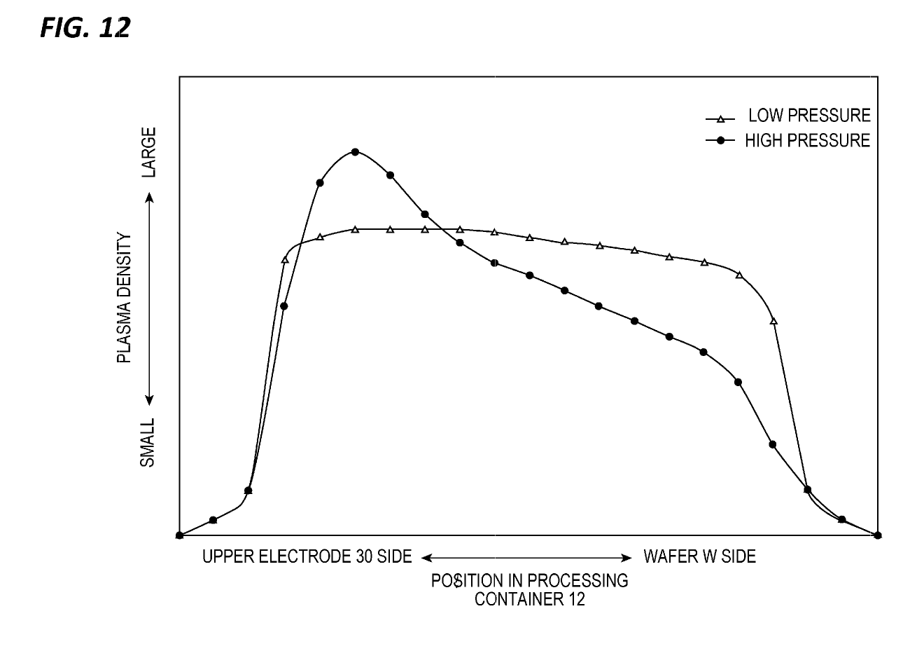

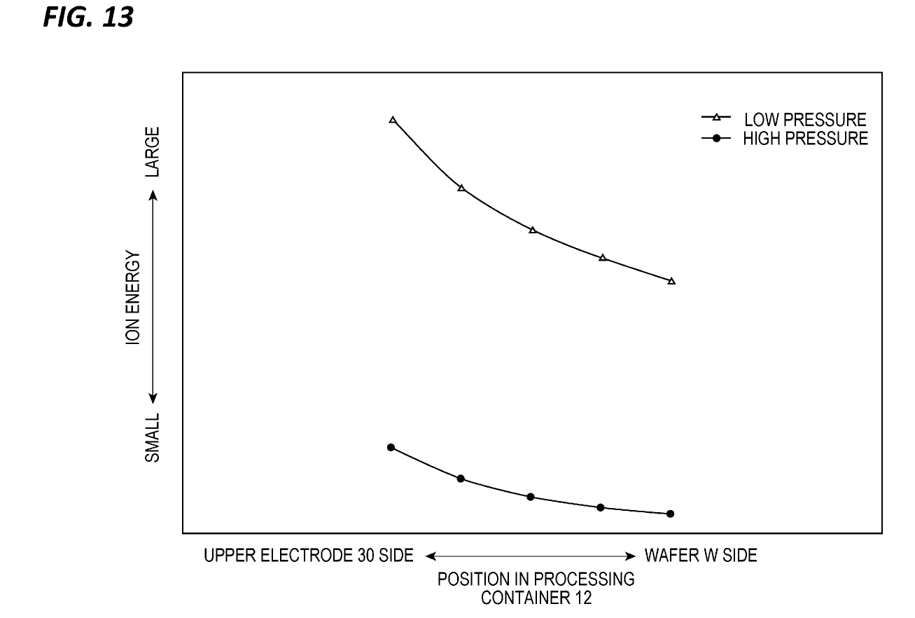

Accordingly, in the condition group CND, the electron density, the sheath voltage, and the ion energy are sufficiently reduced on the wafer W side separated from the upper electrode 30 as illustrated in FIGS. 12 and 13. Thus, in the cleaning of step ST5e in which the condition group CND is used, the etching rate is smaller on the wafer W side than on the upper electrode 30 side.

FIG. 12 illustrates a correlation between a position in the processing container 12 and a plasma density, in which the horizontal axis represents the position in the processing container 12 and the vertical axis represents the plasma density. FIG. 13 illustrates a correlation between a position in the processing container 12 and a plasma density, in which the horizontal axis represents the position in the processing container 12 and the vertical axis represents ion energy. Here, the plasma density means the electron density and the ion density in the plasma. Since the electron density and the ion density are substantially equal, the increase and decrease of the plasma density reflects the increase and decrease of the electron density and the ion density.

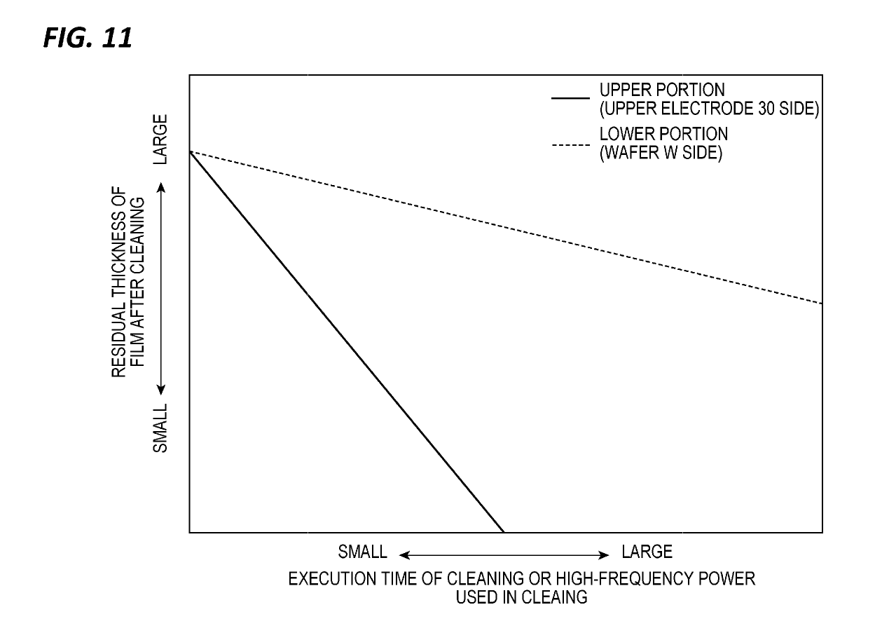

According to the condition group CND, as illustrated in FIG. 11, removal of the thin film SXa on the upper electrode 30 side (the upper portion in the processing container 12) is completed faster than removal of the thin film SXa on the wafer W side (the lower portion in the processing container 12).

FIG. 11 is a diagram representing a correlation between an execution time of the cleaning of the cleaning step (step ST5e) illustrated in FIG. 1 or radio-frequency power used for cleaning in the cleaning step (step ST5e) illustrated in FIG. 1 and a residual thickness of a film SXa after the cleaning. The horizontal axis in FIG. 11 represents a cleaning execution time in step ST5e or the radio-frequency power of the first radio-frequency power supply 62 used for cleaning in step ST5e, and the vertical axis in FIG. 11 represents the residual thickness of the thin film SXa after the cleaning in step ST5e.

In the cleaning in step ST5e, the etching amount (ET [nm]) on the upper electrode 30 side is the product of the etching rate (ER [nm/sec]) on the upper electrode 30 side and the etching time (ET [nm]=ER [nm/sec]×T [sec]). The etching time (T [sec]) is the cleaning execution time in step ST5e. Since the etching rate is roughly proportional to the radio-frequency power (RF [W]) of the first radio-frequency power supply 62, in the cleaning in step ST5e, the etching amount (ET [nm]) on the upper electrode 30 side is proportional to RF [W]×T [sec].

Therefore, when the film thickness (FT [nm]) of the thin film SXa on the upper electrode 30 side at the time of cleaning execution in step ST5e is set to the etching amount (ET [nm]) (FT [nm]=ET [nm]), it is possible to sufficiently remove the thin film SXa on the upper electrode 30 side while sufficiently suppressing etching on the wafer W as represented in FIG. 11 by using RF [W] and T [sec] satisfying FT [nm]=RF [W]×T [sec]. In this manner, the combination of RF [W] and T [sec] that can be set in the cleaning in step ST5e may be suitably selected to match with the condition group CND with a relatively high degree of freedom.

The gas type of the gas G3 may be suitably selected according to the combination of the gas type of the gas G1 and the gas type of the gas G2, that is, in particular, the material of the thin film SXa formed inside the processing container 12.

In the case where the thin film SXa is a material including SiO₂, for example, the gas G1 may be a gas including an organic-containing aminosilane-based gas or a gas including silicon tetrachloride (SiCl₄), and the gas G2 may be a gas including oxygen such as, for example, O₂ gas, CO₂ gas, or CO gas, and the gas G3 may be a gas containing a halogen compound and including fluorine (F) such as, for example, CF₄ gas, NF₃ gas, or SF₆ gas.

In the case where the thin film SXa is a material including tungsten (W), for example, the gas G1 may be a gas including a tungsten halide such as, for example, WF₆ gas, the gas G2 may be a gas including hydrogen (H₂), and the gas G3 may be a gas including fluorine (F) such as, for example, CF₄ gas, NF₃ gas or SF₆ gas.

In the case where the thin film SXa is a material including titanium (Ti) such as, for example, TiO or TiN, for example, the gas G1 may be a gas including titanium tetrachloride (TiCl₄) or tetrakis(dimethylamino)titanium (TDMAT), the gas G2 may be a gas including water (H₂O) or ammonia (NH₃), and the gas G3 may be a gas including a halogen (e.g., F or Cl) such as, for example, CF₄ gas, NF₃ gas, SF₆ gas, or Cl₂ gas.

In the case where the thin film SXa is a material including boron (B) such as, for example, Box or BN, for example, the gas G1 may be a gas including halogenated boron such as, for example, BBr₃ gas or BCl₃ gas and the gas G2 may be a gas including water (H₂O) or ammonia), and the gas G3 may be a gas including halogen (e.g., F or Cl) such as CF₄ gas, NF₃ gas, SF₆ gas, or Cl₂ gas.

In the case where the thin film SXa is an organic film, both the gas G1 and the gas G2 include an organic compound gas. More specifically, in the case where the thin film SXa is an organic film, regarding the gas G1 and the gas G2, (a) the gas G1 may include an electron donating substituent (a first substituent), and the gas G2 may include an electron attracting substituent (a second substituent). Alternatively, (b) the gas G1 may include an electron attracting substituent and the gas G2 may include an electron donating substituent. In the case where the thin film SXa is an organic film, the gas G3 may be a gas including oxygen (O) such as, for example, O₂ gas, CO₂ gas, or CO gas. In the case where the thin film SXa is an organic film, the first step (step ST5a to step ST5d) is a step in which the gas G1 including an electron donating substituent is supplied to the processing space Sp and an electron donating substituent is attracted to the surface of a pattern (a pattern defined by unevenness formed on the surface the wafer W, and the second step (step ST5e to step ST5f) is a step in which the gas G2 including an electron attracting substituent is supplied to the electron donating substituent. In this manner, a deposited film (a thin film forming a protective film SX) may be formed by the polymerization reaction between the material of the gas G1 including the electron donating substituent and the material of the gas G2 including the electron-withdrawing substituent.

In the case where the thin film SXa is an organic film, no plasma is generated in step ST5c, and the thin film SXa which is an organic film is formed by polymerization or thermal polymerization of the material of the gas G1 and the material of the gas G2. Even in the case where the material of the gas G1 and the material of the gas G2 are polymerized or thermally polymerized, self-limiting works similarly to the ALD method.

In the case where the thin film SXa is an organic film, the temperature of the wafer W may be regulated to, for example, 30 degrees Celsius or more and 200 degrees Celsius or less in the thin film forming step (particularly, step ST5a and step ST5c).

The case where the thin film SXa is an organic film will be described in more detail. In the following description in the case where the thin film SXa is an organic film, for convenience, one of the gas G1 and the gas G2 is referred to as a gas GA, and of the gas G1 and the gas G2, the remaining gas other than the gas GA is referred to as a gas GB.

In the case where the thin film SXa is an organic film (urea resin), for example, the gas GA may be a gas including a diamine compound having an electron donating substituent, the gas GB may be a gas including an isocyanate compound having an electron attracting substituent. In the case where the thin film SXa is a urea resin, for example, the gas GA may be a gas including urea having an electron donating substituent, and the gas GB may be a gas including an aldehyde compound having an electron attracting substituent.

In the first step, a deposited film (a thin film forming the protective film SX) may be formed by polymerization reaction of isocyanate and amine or polymerization reaction of isocyanate and a hydroxyl group-containing compound.

In the case where the thin film SXa is a polyamide resin, for example, the gas GA may be a gas including a diamine compound having an electron donating substituent, and the gas GB may be a gas including a dicarboxylic acid compound having an electron attracting substituent.

In the case where the thin film SXa is a polyester resin, for example, the gas GA may be a gas including a diol compound having an electron donating substituent, and the gas GB may be a gas including a dicarboxylic acid compound having an electron attracting substituent.

In the case where the thin film SXa is a polycarbonate resin, for example, the gas GA may be a gas including a bisphenol compound having an electron donating substituent, and the gas GB may be a gas including a phosgene compound having an electron attracting substituent.

In the case where the thin film SXa is a polyurethane resin, for example, the gas GA may be a gas including an alcohol compound having an electron donating substituent, and the gas GB may be a gas including an isocyanate compound having an electron attracting substituent.

In the case where the thin film SXa is an epoxy resin, for example, the gas GA may be a gas including an amine compound or an acid anhydride having an electron donating substituent, and the gas GB may be a gas including an epoxy compound having an electron attracting substituent.

In the case where the thin film SXa is a phenol resin, for example, the gas GA may be a gas including a phenol compound having an electron donating substituent, and the gas GB may be a gas including an aldehyde compound having an electron attracting substituent.

In the case where the thin film SXa is a melamine resin, for example, the gas GA may be a gas including a melamine compound having an electron donating substituent, and the gas GB may be a gas including an aldehyde compound having an electron attracting substituent.

In step ST5f subsequent to step ST5e, the processing space Sp of the processing container 12 is purged. Specifically, the gas G3 supplied in step ST5e is exhausted. In step ST5f, an inert gas such as, for example, nitrogen gas may be supplied into the processing space Sp of the processing container 12 as a purge gas. That is, purge in step ST5f may be either gas purge that causes the inert gas to flow into the processing space Sp of the processing container 12, or purge that is performed as air purge.

In step ST6 subsequent to sequence SQ1, it is determined whether or not execution of sequence SQ1 is ended. Specifically, in step ST6, it is determined whether or not the number of times of execution of sequence SQ1 has reached a preset number of times. The determination of the number of times of execution of sequence SQ1 is to determine the film thickness of the protective film SX deposited on the wafer W.

That is, by the product of the film thickness of the thin film formed by executing sequence SQ1 once (a unit cycle) and the number of times of execution of sequence SQ1, the film thickness of the protective film SX finally formed on the wafer W is substantially determined. Accordingly, the number of times of execution of sequence SQ1 is set depending on the desired film thickness of the protective film SX formed on the wafer W.

When it is determined in step ST6 that the number of times of execution of sequence SQ1 has not reached the preset number (step ST6: NO), execution of sequence SQ1 is repeated again. Meanwhile, when it is determined that the number of times of execution of sequence SQ1 has reached the preset number in step ST6 (step ST6: YES), execution of sequence SQ1 is ended and the process proceeds to step ST7.

As a result, as illustrated in FIG. 4D, a protective film SX of silicon oxide is formed on the main surface of the wafer W. That is, by repeating sequence SQ1 by a preset number of times, the protective film SX having a preset film thickness is conformally formed on the main surface of the wafer W as a uniform film irrespective of the roughness and fineness of the mask MK1.

As illustrated in FIG. 4D, the protective film SX includes regions R11, a region R21, and regions R31. The regions R31 are regions extending on the side surface of the mask MK1 and the side surface of the mask ALM along the side surfaces. The regions R31 extend from the surface of the organic film OL to the lower side of the regions R11. The regions R11 extend on the top surface of the mask MK1 and on the regions R31. The region R21 extends between the adjacent regions R31 and on the surface of the organic film OL.

As described above, since the protective film SX is formed by the same method as the ALD method in sequence SQ1, the respective film thicknesses of the regions R11, R21, and R31 are substantially equal to each other regardless of the roughness and fineness of the mask MK1.

Since the film thickness of the protective film SX formed in the film forming step of sequence SQ1 and step ST6 increases or decreases depending on the temperature of the main surface of the wafer W, it is possible to adjust the film thickness of the protective film SX on the main surface of the wafer W by regulating the temperature of the main surface of the wafer W using a temperature regulation unit HT for each of the plurality of regions ER (see, e.g., FIG. 3) before execution of sequence SQ1 after execution of step ST4.

A description will be made with reference to FIG. 8. Line GRa indicated in FIG. 8 represents a correspondence between the film thickness of a thin film (a film forming the protective film SX) formed by sequence SQ1 and temperature of the main surface of a wafer W on which the film is formed, and corresponds to the Arrhenius equation (Arrhenius plot). The horizontal axis in FIG. 8 represents the temperature of the main surface of the wafer W on which the thin film is formed by sequence SQ1. The vertical axis in FIG. 8 represents the film thickness of the thin film formed by sequence SQ1. In particular, the film thickness represented on the horizontal axis in FIG. 8 is the film thickness of the thin film formed in a time equal to or longer than a time to reach the self-limited region in the ALD method used in sequence SQ1.

As illustrated in FIG. 8, when the temperature of the main surface of the wafer W has a value T1, the film thickness of the film formed on the main surface of the wafer W has a value W1, and the temperature of the main surface of the wafer W has a value T2 (T2>T1), the film thickness of the film formed on the main surface of the wafer W has a value W2 (W2>W1). As described above, in the case of using the ALD method, as the temperature of the main surface of the wafer W is increased, the film thickness of the protective film SX formed on the main surface may be increased.

As described above, sequence SQ1 includes a thin film forming step (steps ST5a to ST5d) in which film formation is performed by a method which is the same as the ALD method, and a cleaning step (step ST5e and step ST5f) of cleaning portions inside the processing container 12 in the upper side of the wafer W (the ceiling side within the processing container 12) every time the thin film forming step is executed once. Since the thin film forming step is the same method as the ALD method, the film thickness of the film formed inside the processing container 12 by one thin film forming step is the film thickness at the level of an atomic layer. For this reason, in the cleaning step executed every time the thin film forming step is executed, since the film having the film thickness at the level of the atomic layer is removed it is possible to sufficiently remove the portion, located above the wafer W, of the film inside the processing container 12 even if the time for executing the cleaning step is sufficiently short.

For example, the processing time for repeating sequence SQ1 20 times on one wafer W may be made shorter, compared to the processing time which is the sum of the processing time for repeating only the thin film forming step 20 times without performing the cleaning step and the processing time for cleaning the inside of the processing container 12 only once (including the processing time required for transporting a wafer in the case of cleaning using the wafer).

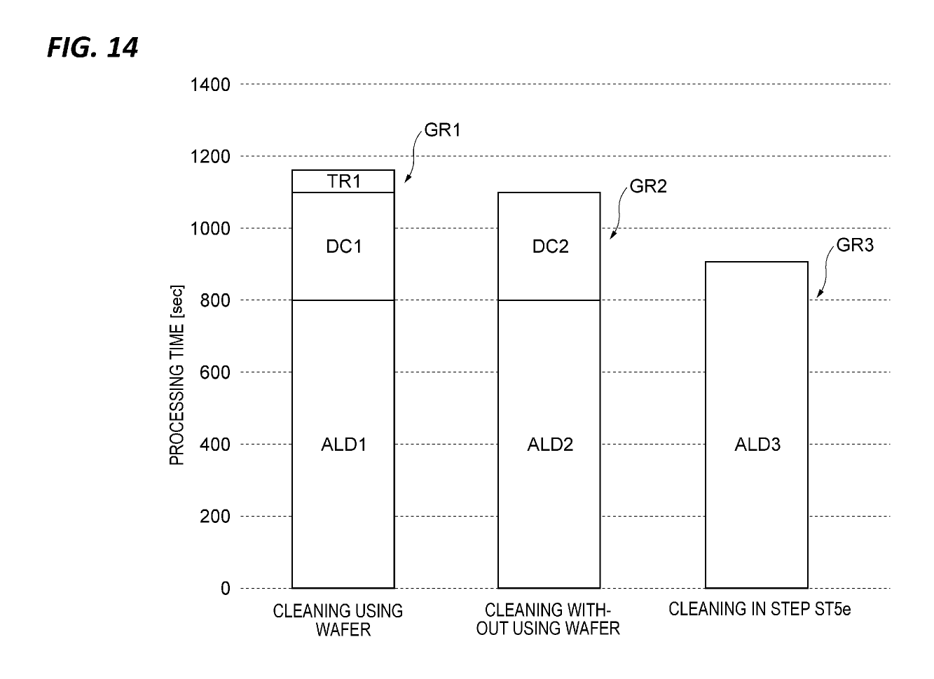

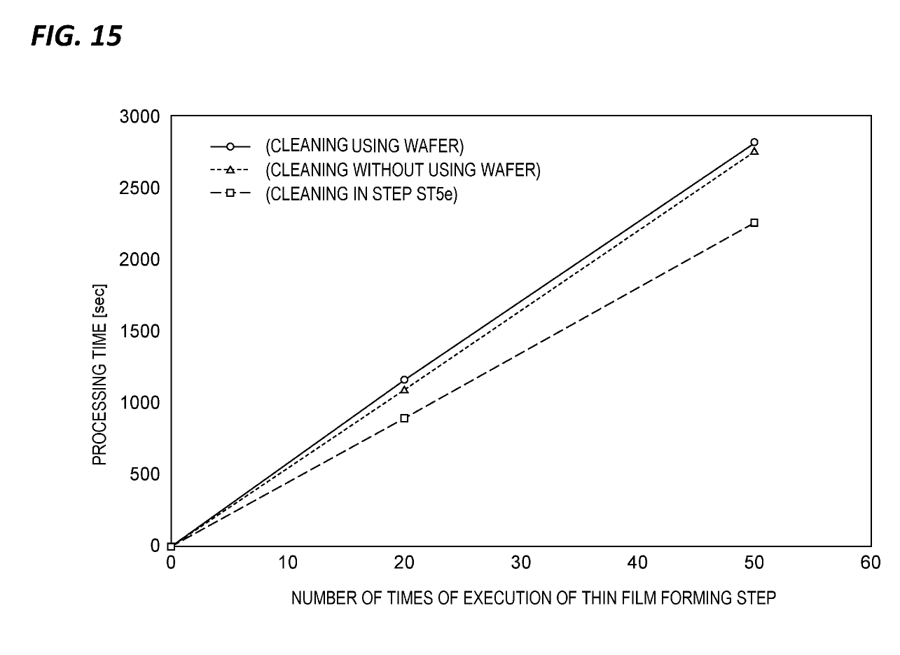

FIG. 14 is a diagram representing a breakdown of the processing time of each wafer W in the case where the thin film forming process is performed 20 times. FIG. 15 is a diagram representing a correlation between the number of times of repeating the thin film forming process for each wafer W and the processing time.

The breakdown of the processing time (referred to as a “processing time TP1”) in the case where only the thin film forming step is repeated 20 times without performing the cleaning step and the cleaning of the inside of the processing container 12 is performed only once using a wafer after repeatedly performing the thin film forming step 20 times is represented in the rectangle GR1 in FIG. 14. In the rectangle GR1, the portion indicated by symbol ALD1 represents the processing time for 20 times of the thin film forming process. Assuming that the processing time for one time of the thin film forming process is about 40 [sec/times], the processing time for 20 times of the thin film forming process is about 800 [sec] (=40 [sec/times]×20 [times]).

In the rectangle GR1, the portion indicated by symbol DC1 represents the processing time required for cleaning the inside of the processing container 12 when the thin film forming process has been repeatedly performed 20 times. When the thin film forming process has been repeatedly performed 20 times, the processing time required for cleaning the inside of the processing container 12 is about 300 [sec]. In the rectangle GR1, the portion indicated by symbol TR1 represents the processing time required for transporting the wafer used for cleaning the inside of the processing container 12. The processing time required for transporting the wafer is about 60 [sec].

Accordingly, the processing time indicated by the rectangle GR1, that is, the processing time TP1 in the case where the thin film forming step is repeated 20 is performed times without performing the cleaning step and cleaning of the inside of the processing container 12 is performed only once using a wafer after repeatedly performing the thin film forming step 20 times is about 1160 sec.

In addition, the breakdown of the processing time (referred to as a “processing time TP1”) in the case where only the thin film forming step is repeated 20 times without performing the cleaning step and the cleaning of the inside of the processing container 12 is performed only once without using a wafer after repeatedly performing the thin film forming step 20 times is represented in the rectangle GR2 in FIG. 14. In the rectangle GR2, the portion indicated by symbol ALD2 represents the processing time for 20 times of the thin film forming process. Assuming that the processing time for one time of the thin film forming process is about 40 sec/times, the processing time for 20 times of the thin film forming process is about 800 sec (=40 sec/times×20 times).

In the rectangle GR2, the portion indicated by symbol DC2 represents the processing time required for cleaning the inside of the processing container 12 when the thin film forming process has been repeatedly performed 20 times. When the thin film forming process has been repeatedly performed 20 times, the processing time required for cleaning the inside of the processing container 12 is about 300 [sec].

Accordingly, the processing time indicated by the rectangle GR2, that is, the processing time TP2 in the case where the thin film forming step is repeated 20 is performed times without performing the cleaning step and cleaning of the inside of the processing container 12 is performed without using a wafer only once after repeatedly performing the thin film forming step 20 times is about 1100 [sec].

Meanwhile, rectangle GR3 in FIG. 14 represents a breakdown of the processing time (referred to as a “processing time TP3”) when sequence SQ1 including a thin film forming step and a cleaning step performed after the thin film forming step is repeatedly performed 20 times. In the rectangle GR3, the portion indicated by symbol ALD3 represents the processing time for 20 times of sequence SQ1 including the thin film forming step and the cleaning step performed after the thin film forming step. Assuming that the processing time of one time of sequence SQ1 including the thin film forming step and the cleaning step is about 45 sec/times, the processing time for 20 times of sequence SQ1 is 900 sec (=45 sec/times×20 times).

As represented in FIG. 15, as the number of times of repeating the thin film forming step increases, the above-described processing time TP1 and processing time TP2 become longer than the processing time TP3 according to the present embodiment, and the difference between them becomes remarkable.

A description will be made returning back to FIG. 1. In step ST7 subsequent to step ST6, the protective film SX is etched (etched back) so as to remove the regions R11 and the region R21. Anisotropic etching conditions are required to remove the regions R11 and the region R21. Therefore, in step ST7, a gas including a fluorocarbon-based gas is supplied from a gas source selected among the plurality of gas sources of the gas source group 40 into the processing space Sp of the processing container 12 through the gas supply pipe 38 and the gas inlet 36c.

Then, radio-frequency power is supplied from the first radio-frequency power supply 62. Radio-frequency bias power is supplied from the second radio-frequency power supply 64. By operating the exhaust device 50, the pressure in the processing space Sp of the processing container 12 is set to a preset pressure. As a result, plasma of fluorocarbon-based gas is generated.

Active species including fluorine in the generated plasma preferentially etches the regions R11 and the region R21 by being drawn in the vertical direction by the radio-frequency bias power. As a result, as illustrated in FIG. 5A, the regions R11 and the region R21 are selectively removed, and the mask MS is formed by the remaining regions R31. The mask MS, the protective film PF, and the mask ALM constitute a mask MK2 on the surface of the organic film OL.

In step ST8 subsequent to step ST7, the organic film OL is etched. Specifically, a gas including nitrogen gas and hydrogen gas is supplied from a gas source selected among the plurality of gas sources of the gas source group 40 into the processing space Sp of the processing container 12 through the gas supply pipe 38 and the gas inlet 36c.

Then, radio-frequency power is supplied from the first radio-frequency power supply 62. Radio-frequency bias power is supplied from the second radio-frequency power supply 64. By operating the exhaust device 50, the pressure in the processing space Sp of the processing container 12 is set to a preset pressure. As a result, plasma of a gas including nitrogen gas and hydrogen gas is generated.

Hydrogen radicals, which are the active species of hydrogen in the generated plasma, etch the regions exposed from the mask MK2 in the entire region of the organic film OL. As a result, as illustrated in FIG. 5B, a mask OLM is formed from the organic film OL. As a gas for etching the organic film OL, a gas including oxygen may be used.

In method MT illustrated in FIG. 1, following step ST8, sequence SQ2 is executed one or more times. As illustrated in FIGS. 5B and 5C, sequence SQ2 is a step of etching a region, not covered with the mask OLM, of the etching target layer, precisely with a high selectivity regardless of the roughness and fineness of the mask OLM by the same method as the ALE method, and includes step ST9a, step ST9b, step ST9c, and step ST9d which are sequentially executed in sequence SQ2.

In step ST9a, plasma of the gas G4 is generated in the processing space Sp of the processing container 12, and as illustrated in FIG. 5B, a mixed layer MX including radicals included in the plasma is formed in an atomic layer on the surface of the etching target layer EL. The mixed layer MX is formed in the atomic layer on the surface of a region, not covered with the mask OLM, of the etching target layer EL. In step ST9a, in the state where the wafer W is placed on the electrostatic chuck ESC, the gas G4 is supplied into the processing space Sp of the processing container 12 to generate the plasma of the gas G4.

The gas G4 is an etchant gas suitable for etching the etching target layer EL including silicon. The gas G4 may include, for example, a fluorocarbon-based gas and a rare gas, and may be, for example, a CxFy/Ar gas. CxFy may be, for example, CF4. Specifically, from a gas source selected among the plurality of gas sources of the gas source group 40, the gas G4 including a fluorocarbon-based gas and a rare gas is supplied into the processing space Sp of the processing container 12 through the gas supply pipe 38 and the gas inlet 36c.

Then, by supplying radio-frequency power from the first radio-frequency power supply 62, supplying radio-frequency bias power from the second radio-frequency power supply 64, and operating the exhaust device 50, the pressure in the processing space Sp of the processing container 12 is set to a preset pressure. In this way, the plasma of the gas G4 is generated in the processing space Sp of the processing container 12. The plasma of gas G4 includes carbon radicals and fluorine radicals.

In FIGS. 9A to 9C, unshaded circles (white circles) indicate atoms forming the etching target layer EL, shaded circles (black circles) indicate radicals, and circled “+” marks indicate ions of atoms of a rare gas (e.g., ions of Ar atoms) included in a gas G5 described below. As illustrated in FIG. 9A, in step ST9a, the carbon radicals and fluorine radicals included in the plasma of the gas G4 are supplied to the surface of the etching target layer EL.

In this way, a mixed layer MX including atoms forming the etching target layer EL, carbon radicals, and fluorine radicals is formed on the surface of the etching target layer EL, as illustrated in FIG. 5B.

As described above, since the gas G4 includes the fluorocarbon-based gas, in step ST9a, fluorine radicals and carbon radicals are supplied to the atomic layer on the surface of the etching target layer EL, and a mixed layer containing both radicals may be formed in the atomic layer MX.

In step ST9b subsequent to step ST9a, the processing space Sp of the processing container 12 is purged. Specifically, the gas G4 supplied in step ST9a is exhausted. In step ST9b, an inert gas such as, for example, nitrogen gas or a rare gas (e.g., Ar gas) may be supplied into the processing space Sp of the processing container 12 as a purge gas. That is, the purge in step ST9b may be either gas purge that causes the inert gas to flow into the processing space Sp of the processing container 12, or purge that is performed as air purge.

In step ST9c subsequent to step ST9b, plasma of the gas G5 is generated in the processing space Sp of the processing container 12, and a bias voltage is applied to the plasma so as to remove the mixed layer MX. The gas G5 may include a rare gas, for example, Ar gas.

Specifically, by supplying the gas G5 including a fluorocarbon-based gas and a rare gas into the processing space Sp of the processing container 12 through the gas supply pipe 38 and the gas inlet 36c from a gas source selected among the plurality of gas sources of the gas source group 40, supplying radio-frequency power from the first radio-frequency power supply 62, supplying radio-frequency bias power from the second radio-frequency power supply 64, and operating the exhaust device 50, the pressure in the processing space Sp of the processing container 12 is set to a preset pressure. In this way, the plasma of the gas G5 is generated in the processing space Sp of the processing container 12.

Ions of atoms of the gas G5 in the generated plasma (e.g., ions of Ar atoms) collide with the mixed layer MX on the surface of the etching target layer EL by drawing the ions of atoms in the vertical direction by the radio-frequency bias power, and provide energy to the mixed layer MX. As illustrated in FIG. 9B, energy is supplied to the mixed layer MX formed on the surface of the etching target layer EL via the ions of atoms of the gas G5 step ST9c, and the mixed layer MX is removed from the etching target layer EL.

As described above, since the gas G5 includes a rare gas, in step ST9c, the mixed layer MX formed on the surface of the etching target layer EL is removed from the surface by the energy received by the plasma of the rare gas by the bias voltage.

In step ST9d subsequent to step ST9c, the processing space Sp of the processing container 12 is purged. Specifically, the gas G5 supplied in step ST9c is exhausted. In step ST9d, an inert gas such as, for example, nitrogen gas or a rare gas (e.g., Ar gas) may be supplied to the processing container 12 as a purge gas. That is, the purge in step ST9d may be either gas purge that causes the inert gas to flow into the processing space Sp of the processing container 12, or purge that is performed as air purge.

As illustrated in FIG. 9C, due to the purge performed in step ST9d, atoms forming the mixed layer MX on the surface of the etching target layer EL and excess ions (e.g., ions of Ar atoms) included in the plasma of the gas G5 are also sufficiently removed.

In step ST10 subsequent to sequence SQ2, it is determined whether or not execution of sequence SQ2 is to be ended. Specifically, in step ST10, it is determined whether or not the number of times of execution of sequence SQ2 has reached a preset number of times. Determination of the number of times of execution of sequence SQ2 is to determine the degree (depth) of etching relative to the etching target layer EL.

Sequence SQ2 may be repeatedly executed so as to etch the etching target layer EL to the surface of the substrate SB. That is, the number of times of execution of sequence SQ2 may be determined such that the product of the thickness of the etching target layer EL to be etched by executing sequence SQ2 once (a unit cycle) and the number of times of execution of sequence SQ2 is the total thickness of the etching target layer EL itself. Therefore, the number of times of execution of sequence SQ2 may be set depending on the thickness of the etching target layer EL.

When it is determined in step ST10 that the number of times of execution of sequence SQ2 has not reached the preset number (step ST10: NO), execution of sequence SQ2 is repeated again. Meanwhile, when it is determined that the number of times of execution of sequence SQ2 has reached the preset number in step ST10 (step ST10: YES), execution of sequence SQ2 is ended.

A portion formed on the inside of the processing container 12 by the thin film forming step (steps ST5a to ST5d) (more specifically, a portion, remaining after the cleaning by the cleaning step (step ST5e and step ST5e), of the thin film SXa formed on the inside of the processing container 12 (the thin film SXa in the state represented by a state CON2 in FIG. 10)) is completely removed by the step including sequence SQ2 and step ST10 described above, as illustrated in a state CON1 in FIG. 10.

As described above, in the step including sequence SQ2 and step ST10, sequence SQ2 is repeatedly performed using the mask OLM in the same manner as the ALE method so as to remove the etching target layer EL for each atomic layer, precisely etching the etching target layer EL.

By executing the above-described method MT illustrated in FIG. 1, for example, the following effects can be obtained. Since the cleaning step (step ST5e and step ST5f) is performed each time a thin film is formed by executing the thin film forming step (step ST5a to step ST5d) once, it becomes easy to remove the corresponding thin film by the cleaning step for the region above the wafer W in the processing container 12 (the upper electrode 30 side region in the processing container 12).

In the thin film forming step, a reaction precursor (e.g., the layer Ly1 illustrated in FIG. 7B) is formed on the main surface of the wafer W by the gas G1, so that a thin film is conformally formed on the reaction precursor by the gas G2. This thin film may also be formed in the processing container 12, but, with respect to a region in the processing container 12 above the wafer W (the upper electrode 30 side region in the processing container 12), the thin film is removed (cleaned) by the plasma of the gas G3 generated using the radio-frequency power supplied from the upper electrode 30 of the processing container 12.

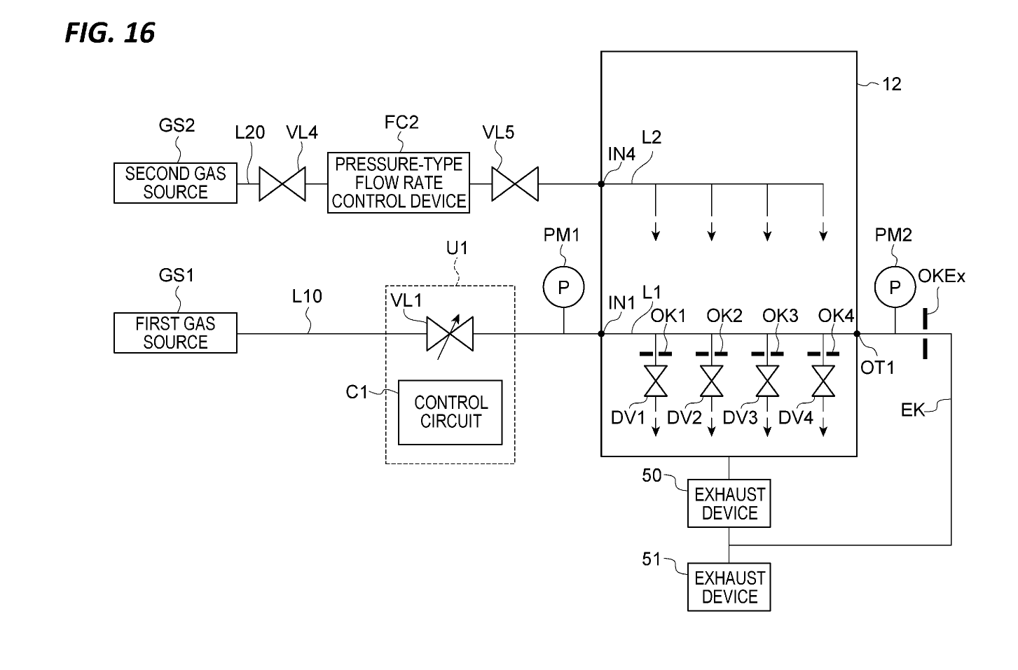

The configuration for supplying a gas is not limited to that illustrated in FIG. 2. That is, a gas supply system 1 illustrated in FIG. 16 may be used, rather than using the gas inlet 36c, the gas supply pipe 38, the gas source group 40, the valve group 42, the flow rate controller group 45, the gas inlet 52a, and the gas supply pipe 82 illustrated in FIG. 2. FIG. 16 is a schematic diagram of the gas supply system 1. The gas supply system 1 illustrated in FIG. 16 is an exemplary system that supplies a gas to the processing space Sp in the processing container 12 of the plasma processing apparatus 10. The gas supply system 1 illustrated in FIG. 16 includes a first flow path L1, a second flow path L2, a gas ejection hole 34a, a gas ejection hole 34b, a plurality of diaphragm valves (a diaphragm valve DV1, a diaphragm valve DV2, a diaphragm valve DV3, and a diaphragm valve DV 4).

The first flow path L 1 is connected to the first gas source GS1 of the first gas. The first flow path L1 is formed inside a ceiling member (e.g., the upper electrode 30) constituting the ceiling of the processing space Sp or inside the sidewall of the processing container 12. A plurality of gas ejection holes 34b communicate the first flow path L1 with the processing space Sp. The second flow path L2 is connected to the second gas source GS2 of the second gas. The second flow path L 2 is formed inside the ceiling member or inside the sidewall of the processing container 12. A plurality of gas ejection holes 34a communicate the second flow path L2 with the processing space Sp. Each of the plurality of diaphragm valves (the diaphragm valves DV1 to DV4) is provided in correspondence with the gas ejection holes 34b between the first flow path L1 and the gas ejection holes 34b.

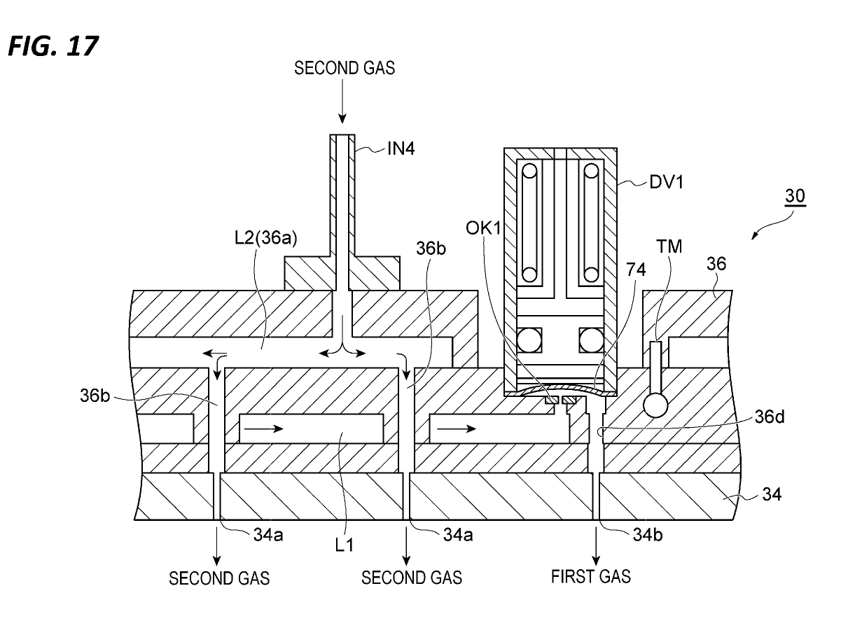

The configuration of the gas supply system 1 will be described in more detail with reference to FIG. 17 together with FIG. 16. FIG. 17 is a schematic cross-sectional view of the upper electrode 30 when the gas supply system 1 illustrated in FIG. 16 is used. The gas supply system 1 includes the first gas source GS1 and the second gas source GS2. The first gas source GS1 stores the first gas. The second gas source GS2 stores the second gas. The first gas and the second gas are optional. As an example, the second gas may be a main process gas and the first gas may be an added process gas. In addition, the gas G1 may be a gas introduced into the processing space Sp from the gas inlet 52a, and the gas G2 may be a gas introduced into the processing space Sp from the gas inlet 36c.

The gas supply system 1 includes a main flow path L10 and a second main flow path L20. The first main flow path L10 connects the first gas source GS1 and the first flow path L1 of the processing container 12 to each other via a supply port IN1. The second main flow path L20 connects the second gas source GS2 and the second flow path L2 of the processing container 12 to each other via a supply port IN4. The first main flow path L10 and the second main flow path L20 are formed of, for example, a pipe. The second flow path L2 illustrated in FIGS. 16 and 17 corresponds to the gas diffusion chamber 36a illustrated in FIG. 1.

The first flow path L1 is connected to the first gas source GS1 and formed inside the upper electrode 30 (an exemplary ceiling member) of the processing container 12 or inside the sidewall of the processing container 12. The first flow path L1 has a supply port IN1 to which the first gas is supplied and an exhaust port OT1 through which the first gas is exhausted, and extends from the supply port IN1 to the exhaust port OT1. The exhaust port OT1 is connected to an exhaust device 51 configured to evacuate the processing container 12 via an exhaust flow path EK.

The first flow path L1 and the processing space Sp in the processing container 12 are communicated with each other through the plurality of gas ejection holes 34b. The first gas is supplied to the processing space Sp of the processing container 12 from the plurality of gas ejection holes 34b connected to the first flow path L1.

Between the first flow path L1 and the gas ejection holes 34b, one diaphragm valve is provided so as to correspond to one gas discharge hole 34b. That is, the gas supply system 1 includes a plurality of diaphragm valves corresponding to the plurality of gas discharge holes 34b. As an example, in FIG. 16, four diaphragm valves (diaphragm valves DV1 to DV4) corresponding to four gas discharge holes 34b are illustrated. Each of the four diaphragm valves (e.g., the diaphragm valve DV1) operates independently.

An example of a diaphragm valve is an ON/OFF valve. The number of gas discharge holes 34b is not limited to four, but may be two or more. In addition, the plurality of diaphragm valves may be provided to correspond to the plurality of gas discharge holes 34b, respectively, and the number of the diaphragm valves is not limited to four.

Between the first flow path L1 and the gas ejection holes 34b, one orifice may be provided so as to correspond to one gas ejection hole 34b. The orifice is arranged on the upstream side of the diaphragm valve. As an example, in FIG. 16, four orifices (orifices OK1 to OK4) are illustrated. Each diaphragm valve controls the supply timing of the first gas supplied from the outlet of an orifice to a gas ejection hole 34b. The plurality of orifices may be provided to correspond to the plurality of gas ejection holes 34b, respectively, and the number of orifices is not limited to four.

The first second path L2 is connected to the second gas source GS2 and formed inside the upper electrode 30 of the processing container 12 or inside the sidewall of the processing container 12. The second flow path L2 is connected to the plurality of gas ejection holes 34a. The second gas is supplied to the processing space Sp of the processing container 12 from the plurality of gas ejection holes 34b each of which is connected to the first flow path L2.

The gas supply system 1 may include a pressure-type flow rate control device FC. The pressure-type flow rate control device FC is disposed on the downstream side of the second gas source GS2 in the second main flow path L20. A primary valve VL4 is provided on the upstream side of the pressure-type flow control device FC and a secondary valve VL5 is provided on the downstream side of the pressure-type flow control device FC.

In addition, the flow rate control device is not limited to the pressure-type flow rate control device and may be a thermal flow rate control device or a flow rate control device based on other principles.

The second gas of the second gas source GS2 is regulated in flow rate and pressure by the pressure-type flow rate control device FC and supplied to the second flow path L2 of the processing container 12 through the supply port IN4.

The gas supply system 1 may include a control valve VL1. The control valve VL1 is disposed on the downstream side of the first gas source GS1 in the first main flow path L10. The control valve VL1 is provided upstream of the supply port IN1 and controls the first gas supplied to the supply port IN1 to a preset pressure.

The control valve VL1 has the same function as the control valve of the pressure-type flow rate control device FC. A first pressure detector PM1 may be disposed in the flow path between the control valve VL1 and the supply port IN1.

As an example, the control valve VL1 controls the flow rate of the first gas based on the detection result of the first pressure detector PM1. As a more specific example, a control circuit C1 determines the operation of the control valve VL1.

The control circuit C1 inputs the pressure detected by the first pressure detector PM1 and calculates the flow rate of the detected pressure. Then, the control circuit C1 compares the set target flow rate with the calculated flow rate, and determines the operation of the control valve VL1 such that the difference therebetween becomes small.

A primary valve may be provided between the first gas source GS1 and the control valve VL1. A secondary valve may be provided downstream of the control valve VL1 and upstream of the first pressure detector PM1. Further, the control circuit C1 and the control valve VL1 may be unitized as a unit U1.

The gas supply system 1 may further include a second pressure detector PM2 configured to detect the pressure of the first gas exhausted from the exhaust port OT1. In this case, the control valve VL1 controls the flow rate of the first gas, for example, based on the detection results of the first pressure detector PM1 and the second pressure detector PM2.

More specifically, the pressure of the first gas at the arrangement position of each orifice is calculated based on the detection result of the first pressure detector PM1 and the detection result of the second pressure detector PM2. Then, based on the pressure calculation result, the supply timing of the first gas by each diaphragm valve is controlled.

The gas supply system 1 may include a temperature detector TM (see, e.g., FIG. 17) configured to detect the temperature of the first gas in the first flow path L1. In this case, similarly to the control valve provided in the pressure-type flow rate control device FC, the control valve VL1 performs flow rate correction using the temperature detector TM. Specifically, the control valve VL1 controls the flow rate of the first gas based on the detection result of the temperature detector TM.

The first gas of the first gas source GS1 is regulated in flow rate and pressure by the control valve VL1 and supplied to the first flow path L1 of the processing container 12 through the supply port IN1. In addition, the exhaust port OT1 of the first flow path L1 may be provided with an exhaust orifice OKEx.

The control unit Cnt of the plasma processing apparatus 10 operates the control valve VL1 and the plurality of diaphragm valves (e.g., the diaphragm valves DV1 to DV4) in the gas supply system 1.

In the gas supply system 1, the controller Cnt inputs a recipe stored in the storage unit and outputs a signal to the control circuit C1 that operates the control valve VL1. In the gas supply system 1, the controller Cnt inputs the recipe stored in the storage unit and controls the opening and closing operations of the plurality of diaphragm valves (e.g., the diaphragm valves DV1 to DV4). In the gas supply system 1, the controller Cnt may operate the exhaust device 51 via the control circuit C1.

An exhaust device 50 and an exhaust device 51 are connected to the exhaust port 12e via an exhaust pipe 52. The exhaust device 50 is a turbo molecular pump, and the exhaust device 51 is a dry pump. The exhaust device 50 is provided on the upstream side of the exhaust device 51 with respect to the processing container 12.

The exhaust flow path EK of the gas supply system 1 is connected to the pipe between the exhaust device 50 and the exhaust device 51. By connecting the exhaust flow path EK between the exhaust device 50 and the exhaust device 51, backflow of the gas from the exhaust flow path EK into the processing container 12 is suppressed.

As illustrated in FIG. 17, the first flow path L1 and the second flow path L2 extending in the horizontal direction are provided inside the electrode support 36 of the upper electrode 30. The first flow path L1 is positioned below the second flow path L2.

The electrode support 36 is provided with a plurality of gas flow holes 36d that connect the first flow path L1 and the plurality of gas ejection holes 34b extending below the first flow path L1. An orifice OK1 and a diaphragm valve DV1 are provided between the first flow path L1 and the gas discharge holes 34 b of the electrode support 36. A sealing member 74 that exerts a valve function is disposed below the diaphragm valve DV1.

The sealing member 74 may be formed of a flexible member. The sealing member 74 may be, for example, an elastic member, a diaphragm, or a bellows.

When the diaphragm valve DV1 is opened, the first gas flowing through the first flow path L1 passes through the outlet of the orifice OK1, the gas flow holes 36d, and the gas ejection holes 34b so as to be supplied to the processing space Sp. Other gas ejection holes 34b also have the same configuration. The electrode support 36 is provided with a temperature detector TM such that the control valve VL1 performs flow rate correction.

The electrode support 36 is provided with a plurality of gas flow holes 36b that connect the second flow path L2 and the plurality of gas ejection holes 34a extending below the second flow path L2. The second gas is supplied through the supply port IN4, and is supplied to the processing space Sp through the plurality of gas flow holes 36b and the plurality of gas ejection holes 34a.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A film forming method comprising:
placing a substrate formed with a pattern on a pedestal provided in a space configured to perform a plasma processing therein under a reduced pressure environment;
supplying radio-frequency electric power using an upper electrode disposed to face the pedestal in the space; and
repeating a sequence including forming a film on the pattern of the substrate and cleaning the space by supplying electric power only to the upper electrode so as to generate plasma in the space.

2. The film forming method of claim 1, wherein the forming includes:
supplying a first gas including a material of a precursor to the space so as to cause the precursor to be adsorbed to the surface of the pattern, and
generating plasma of a second gas so as to supply the plasma to the precursor.

3. The film forming method of claim 2, wherein the first gas is an aminosilane-based gas.

4. The film forming method of claim 2, wherein the second gas contains oxygen or nitrogen.

5. The film forming method of claim 2, wherein, in the cleaning, plasma of a third gas is generated in the space, and
the third gas contains a halogen compound.

6. The film forming method of claim 2, wherein the aminosilane-based gas of the first gas includes aminosilane having 1 to 3 silicon atoms.

7. The film forming method of claim 2, wherein the aminosilane-based gas of the first gas includes aminosilane having 1 to 3 amino groups.

8. The film forming method of claim 2, wherein the first gas contains tungsten halide.

9. The film forming method of claim 2, wherein the first gas contains titanium tetrachloride or tetrakis(dimethylamino)titanium.

10. The film forming method of claim 2, wherein the first gas contains halogenated boron.

11. The film forming method of claim 1, wherein the forming includes:
supplying a first gas including an electron-donating first substituent so as to cause the first substituent to be adsorbed to the surface of the pattern and
supplying a second gas including an electron-attracting second substituent to the first substituent.

12. The film forming method of claim 1, wherein the forming forms the film by polymerization reaction of isocyanate and amine, or polymerization reaction of isocyanate and a hydroxyl group-containing compound.

13. A processing method comprising:
providing a substrate on a pedestal in a space within a chamber;
forming a film on the substrate by atomic layer deposition;
cleaning the space by generating a plasma in the space; and
repeating the forming and the cleaning several times.

14. The processing method of claim 13, further comprising:
providing an upper electrode to face the substrate on the pedestal;
supplying an electric power to the upper electrode in the cleaning of the space.

15. The processing method of claim 13, wherein the forming a film includes:
supplying a first gas including a precursor to the space to form an adsorbed surface of the substrate, and
generating plasma of a second gas to expose the adsorbed surface to the plasma.

16. The processing method of claim 13, further comprising:
etching of the substrate after the repeating the forming and the cleaning several times.

17. The processing method of claim 13, wherein the cleaning includes supplying F-containing gas.

18. The processing method of claim 17, wherein the F-containing gas is CF₄, NF₃, or SF₆.
